(19) United States
(12) Patent Application Publication
(10) Pub. No.: US 2026/0153550 A1
(43) Pub. Date: Jun. 4, 2026

(54) ON-DIE VOLTAGE NOISE MONITOR FOR SUPPLY NOISE DETECTION UTILIZING CONTROLLABLE RESISTORS FOR THRESHOLD LEVEL PROGRAMMING

(71) Applicant: NVIDIA Corporation, Santa Clara, CA (US)

(72) Inventors: Harun Demircioglu, San Jose, CA (US); Miguel Rodriguez, Golden, CO (US); Jiale Liang, San Jose, CA (US); Tezaswi Vatsavai Raja, San Jose, CA (US)

(21) Appl. No.: 18/965,166

(22) Filed: Dec. 2, 2024

(51) Int. Cl. G01R 29/26; G01R 19/00; G01R 35/00

(52) U.S. Cl. CPC G01R 29/26; G01R 19/0084; G01R 35/005

(57) ABSTRACT

Systems and methods are disclosed that monitor for supply noise from a power source using a voltage noise monitor (VNM). For instance, the VNM may include voltage sense circuitry comprising a controllable resistor that is controlled using threshold information. The resistance of the controllable resistor may be changed based on closing and/or opening one or more switches associated with step resistors using the bits from the threshold information. Furthermore, the VNM may include digital circuitry that comprises a hold finite state machine and a sticky hold counter. Using the digital circuitry, the VNM may be configured to hold a noise detection event for a plurality of clock cycles. In addition, the VNM may perform a calibration process based on setting two voltages for the power source to obtain two codes, and determining a transfer function based on the two voltages and the two codes.

### BACKGROUND

With the ever-increasing demand for computational power, current consumption and/or demand may experience an increase, and supply noise may become a critical issue in modern system-on-chips (SoCs). Supply noise (e.g., voltage undershoots and overshoots) may impact timing closure and reliability, which may constrain the maximum product performance. A large undershoot noise may cause a critical timing path to fail, requiring increased voltage margins and therefore reducing the performance per power of a product. Conversely, a large overshoot may cause hold failures or impact static random access memory (SRAM) reliability, and thus limiting the maximum voltage level applied (Vₘₐₓ) as well as maximum performance. In addition, with the variations in chip current consumption, supply noise magnitude and duration may be affected by the interaction of board, package, and/or die level parasitics. Noise events may occur with different time constants, and high frequency noise events typically have the most pronounced impact on the performance of the chip. Furthermore, within large dies, the noise may exhibit a distributed nature when localized activity causes voltage noise events within that region. As such, there is a need for addressing these issues and/or other issues associated with the prior art.

### SUMMARY

Embodiments of the present disclosure may relate to monitoring supply noise utilizing one or more voltage noise monitors (VNMs). For instance, embodiments of the present disclosure may include systems and methods for using an on-die VNM for supply noise detection that utilizes controllable resistors for threshold level programming. In some instances, the VNM may be compact (e.g., may have an area of 1350 square micrometers (μm²)) and may be configured to measure voltage noise events at multiple locations on a chip, die, and/or SoC. The VNM may have a simplified calibration scheme to mitigate detection variations. Additionally, and/or alternatively, the VNM might not require an analog supply rail and may operate in the same domain within which noise is to be detected (e.g., in a range of 0.55 Volts (V) to 1.4 V).

In some examples, the VNMs may have a faster response time and better accuracy than small digital sensors that were previously used. In addition, the VNMs may be configured to function as a noise detector for both undershoots and overshoots (e.g., the VNMs may be used for distributed sensing for rapid overshoot control).

In some instances, the VNM may be a mixed signal macro that includes an analog domain and a digital domain. For instance, the analog portion of the VNM may include a plurality of fast voltage comparators, programmable sense voltage generators for each comparator with a tunable filter for noise bandwidth, and an input resistor with a low pass filter to create a voltage reference. The plurality of comparators may enable the detection of voltage noise events in different magnitudes. In addition, as mentioned above, the VNMs may be compact and configured to measure voltage noise events at multiple locations by instantiating multiple instances of the VNM with a shared current reference. The VNM may also include a simplified calibration scheme that mitigates detection variations.

In an embodiment, a VNM that is configured to monitor supply noise from a power source is provided. The system includes analog circuitry comprising sense voltage (Vsense) circuitry, reference voltage generation circuitry, and one or more comparators. The Vsense circuitry comprises one or more Vsense circuits, and each of the one or more Vsense circuits comprises a controlled resistor that is tunable based on threshold information from a micro-processor. Further, each of the one or more Vsense circuits outputs a sense voltage based on a resistance of the controlled resistor and a supply voltage from the power source. The reference voltage generation circuitry is configured to generate a reference voltage based on a reference current from an external reference current source. In addition, each of the one or more comparators is configured to receive the sense voltage from a Vsense circuit of the one or more Vsense circuits, receive the reference voltage from the reference voltage generation circuitry, and generate a comparator output signal indicating whether a noise detection event is occurring based on a comparison between the sense voltage and the reference voltage.

### BRIEF DESCRIPTION OF THE DRAWINGS

The present systems and methods for a VNM to monitor for supply noise from a power source are described in detail below with reference to the attached drawing figures, wherein:

FIG. 1A illustrates a general overview of an environment for using one or more VNMs to monitor for supply noise from a power source, in accordance with an embodiment;

FIG. 1B shows a block diagram of the analog circuitry of a VNM from FIG. 1A, in accordance with an embodiment;

FIG. 1C shows an exemplary reference voltage generation circuitry, in accordance with an embodiment;

FIG. 1D shows an exemplary sense voltage (Vₛₑₙₛₑ) circuit, in accordance with an embodiment;

FIG. 1E shows an exemplary Vₛₑₙₛₑ circuitry, in accordance with an embodiment;

FIG. 1F shows an exemplary controlled resistor from FIG. 1D with switches that are controlled utilizing the threshold information, in accordance with an embodiment;

FIG. 2A shows a block diagram of the digital circuitry of a VNM from FIG. 1A, in accordance with an embodiment;

FIG. 2B shows a portion of the digital circuitry from FIG. 2A, in accordance with an embodiment;

FIG. 2C shows a graphical representation for calibrating the VNM, in accordance with an embodiment;

FIG. 2D shows a calibration state machine that is used to calibrate the VNM, in accordance with an embodiment;

FIG. 2E shows a timing diagram that is used to calibrate the VNM, in accordance with an embodiment;

FIG. 3 provides a flow diagram illustrating a method for using a VNM to monitor for supply noise from a power source, in accordance with an embodiment;

FIG. 4 illustrates an example parallel processing unit suitable for use in implementing some embodiments of the present disclosure;

FIG. 5A is a conceptual diagram of a processing system implemented using the PPU of FIG. 4, suitable for use in implementing some embodiments of the present disclosure;

FIG. 5B illustrates an exemplary system in which the various architecture and/or functionality of the various previous embodiments may be implemented;

FIG. 5C illustrates components of an exemplary system that can be used to train and utilize machine learning, in at least one embodiment; and

FIG. 6 illustrates an exemplary game streaming system suitable for use in implementing some embodiments of the present disclosure.

### DETAILED DESCRIPTION

Systems and methods are disclosed herein that relate to using one or more VNMs to monitor for supply noise from a power source, and in particular, to using on-die VNMs for supply noise detection that utilizes controllable resistors for threshold level programming. For instance, the VNM includes an analog portion and a digital portion that are used to detect undershoot noise and/or overshoot noise. As mentioned above, by using the VNMs to monitor for undershoot noise events and/or overshoot noise events, numerous advantages may be achieved, including, but not limited to, increasing the performance per power of the SoC such as by preventing a critical timing path to fail in an undershoot noise event, which allows for decreased voltage margins. In addition, by enabling the monitoring of noise overshoot events, the VNMs may further prevent hold failures and/or increase SRAM reliability, which relaxes the limitation of the maximum voltage level applied to the SoC and thus increases the maximum performance of the SoC.

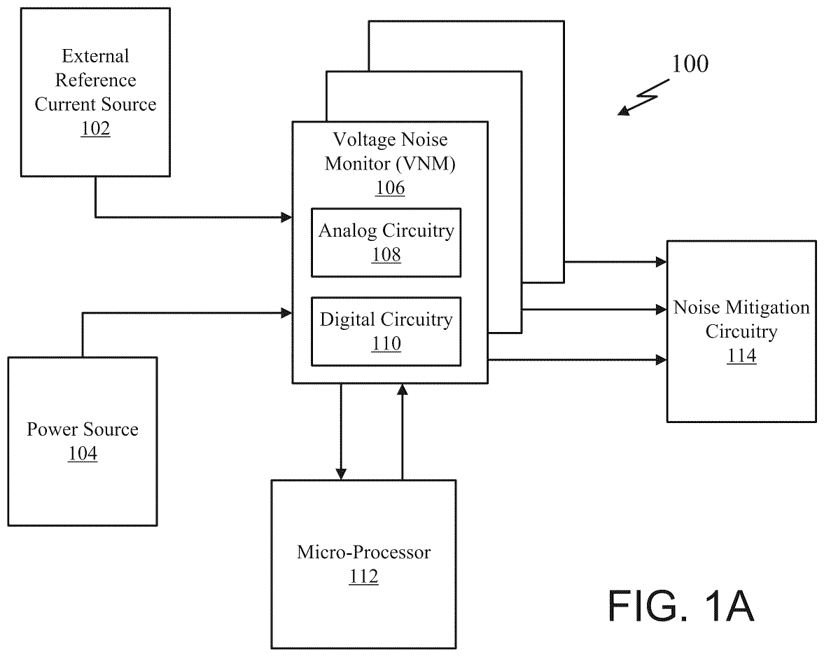

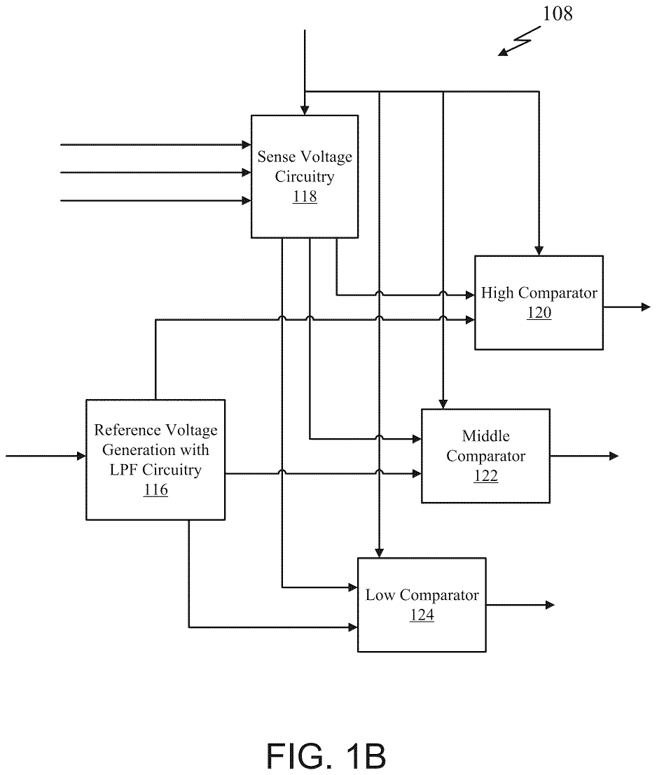

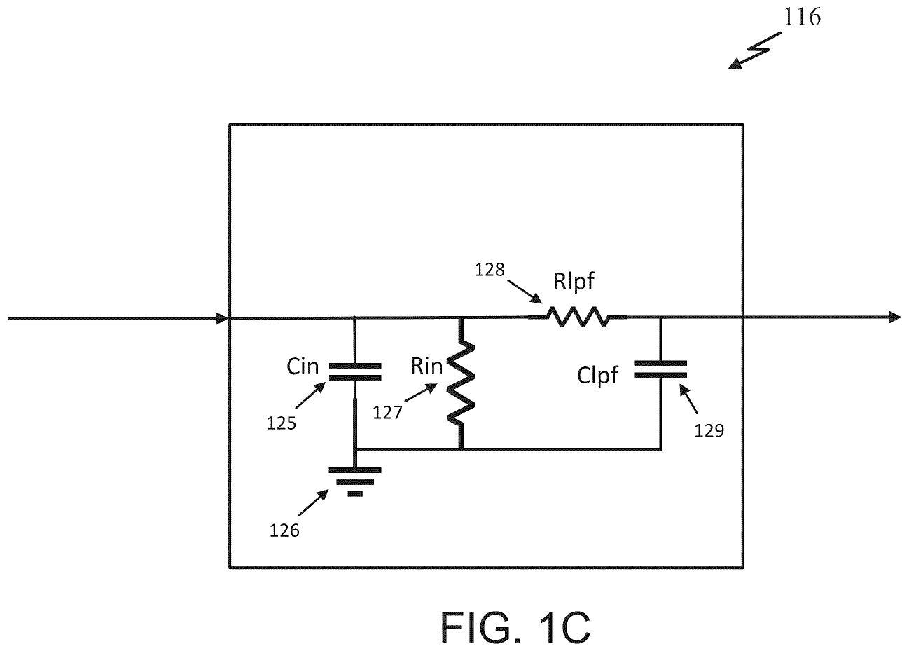

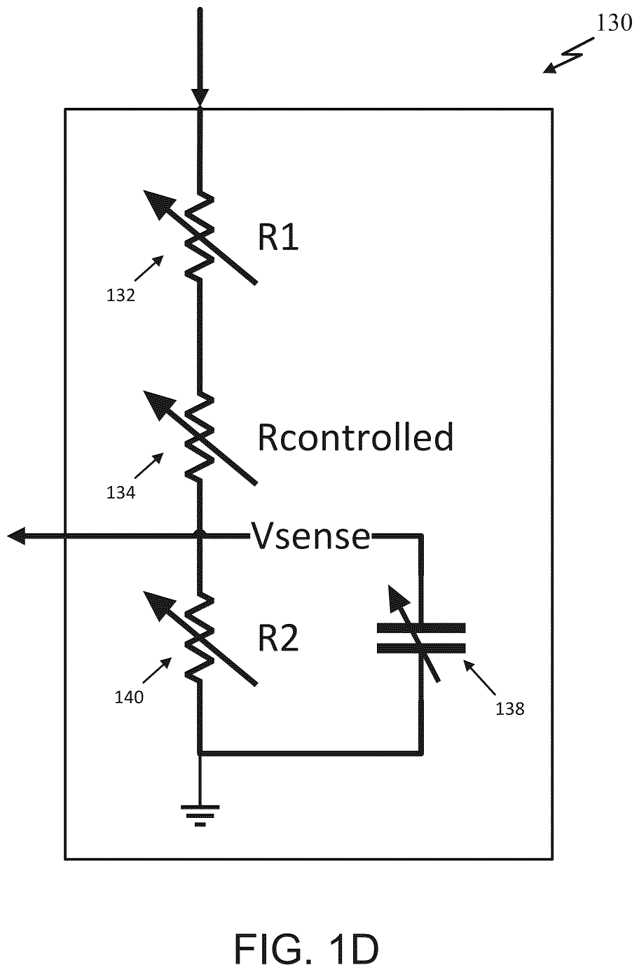

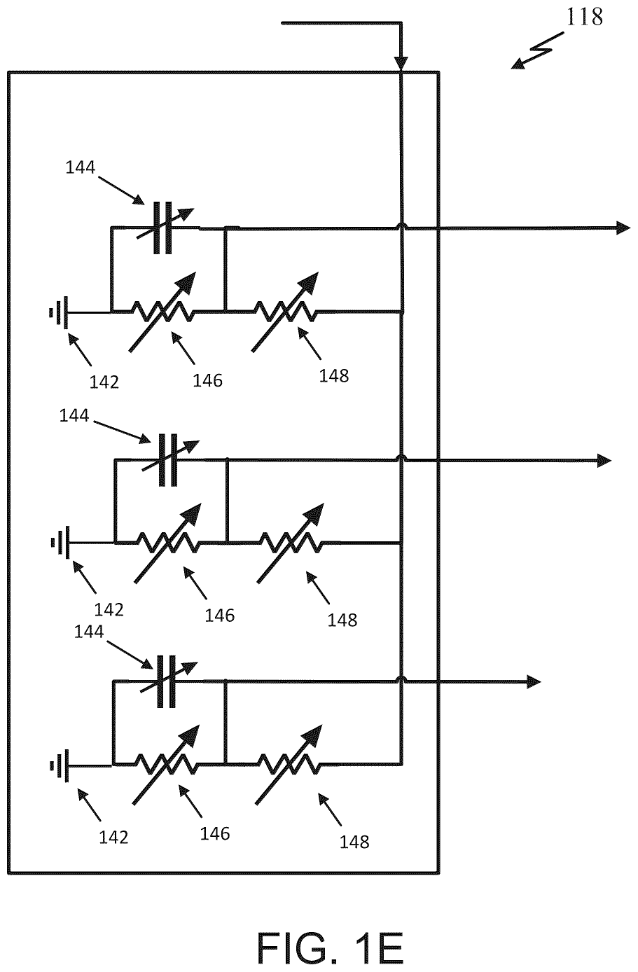

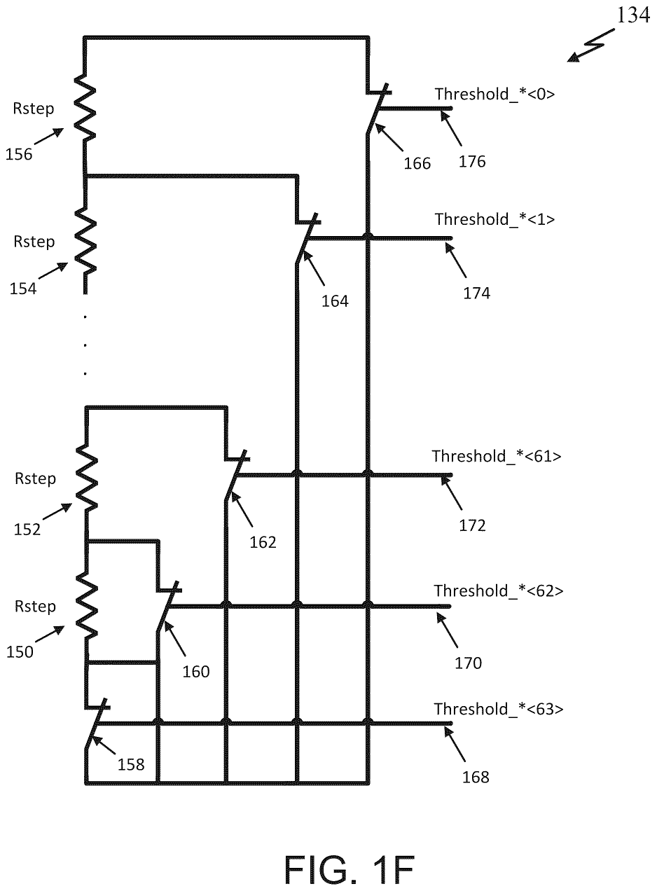

FIG. 1A illustrates a general overview 100 of an environment for using one or more VNMs 106 to monitor for supply noise from a power source 104, in accordance with an embodiment. For example, the overview 100 includes an external reference current source 102, a power source 104, one or more VNMs 106, a micro-processor 112, and noise mitigation circuitry 114. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory. Furthermore, persons of ordinary skill in the art will understand that any system that performs the operations of the overview 100 and/or the VNMs 106 is within the scope and spirit of embodiments of the present disclosure.

In some embodiments, one or more elements of FIG. 1A may be positioned on a SoC. For instance, the SoC may include four VNMs that are positioned on various physical locations of the SoC, and each of the VNMs may be configured to detect noise events from the power source 104. In other words, by having multiple VNMs at various locations, the VNMs may be able to detect noise events that are impacting different areas or regions of the SoC (e.g., a first VNM 106 may detect a noise event that is impacting a left region of the SoC, but a second VNM 106 that is on the right region of the SoC might not be detecting the noise event). Additionally, and/or alternatively, other elements of the overview 100 such as the noise mitigation circuitry 114 and/or the micro-processor 112 may also be part of the SoC. In some embodiments, one or more elements of the overview 100 (e.g., the external reference current source 102 and/or the power source 104) might not be part of the SoC. Additionally, and/or alternatively, by using multiple VNMs 106 at various locations, this may further reduce latency for the downstream reaction mechanism (e.g., the noise mitigation circuitry 114) for noise mitigation.

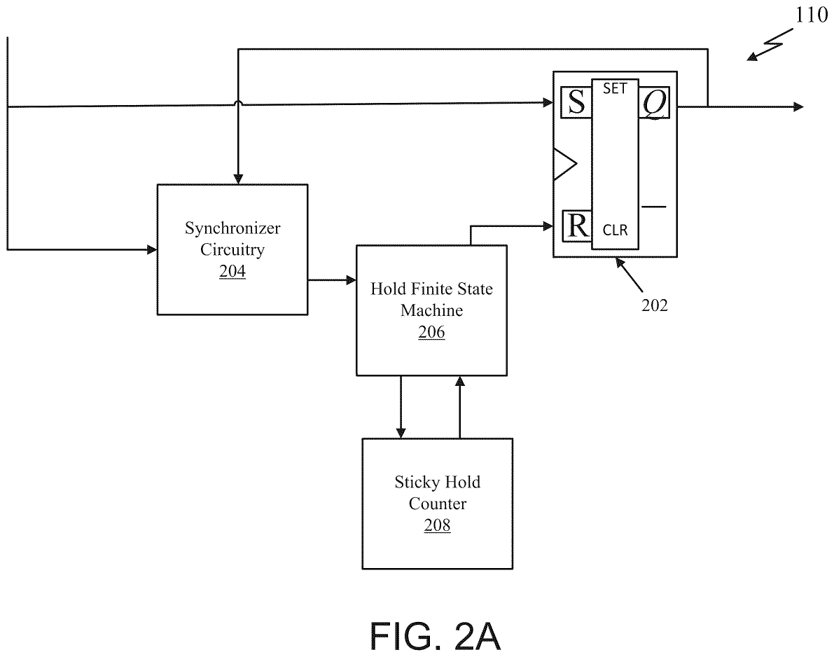

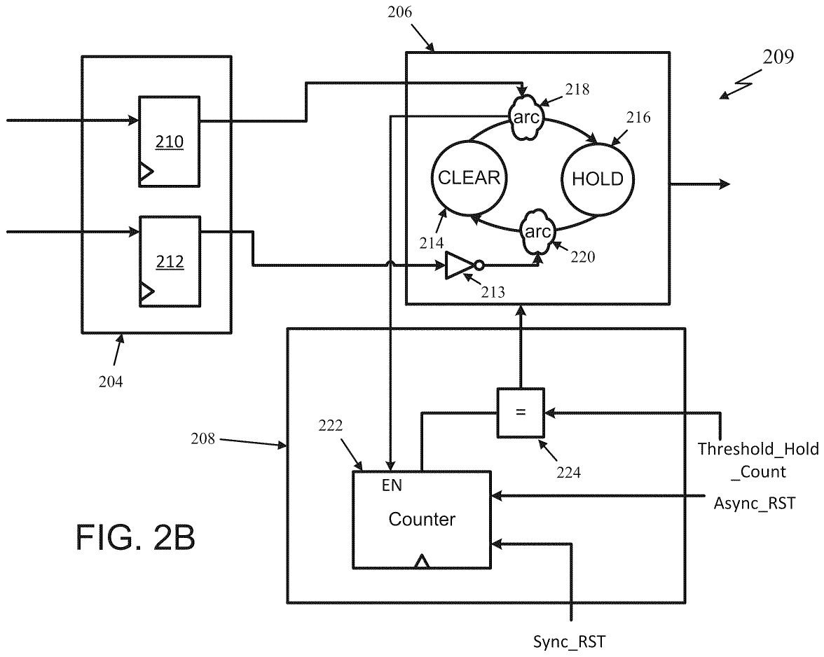

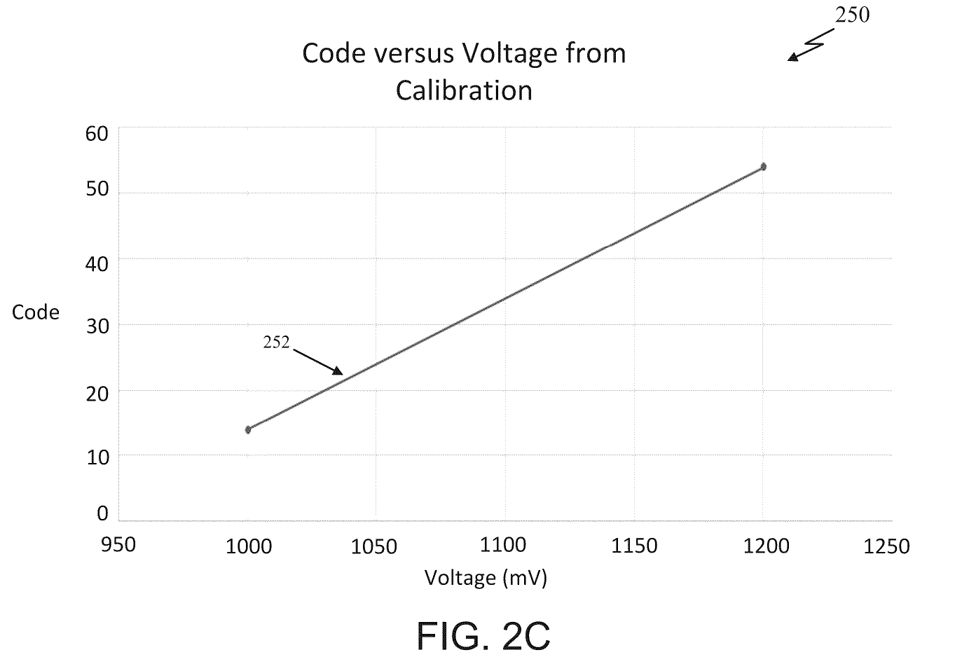

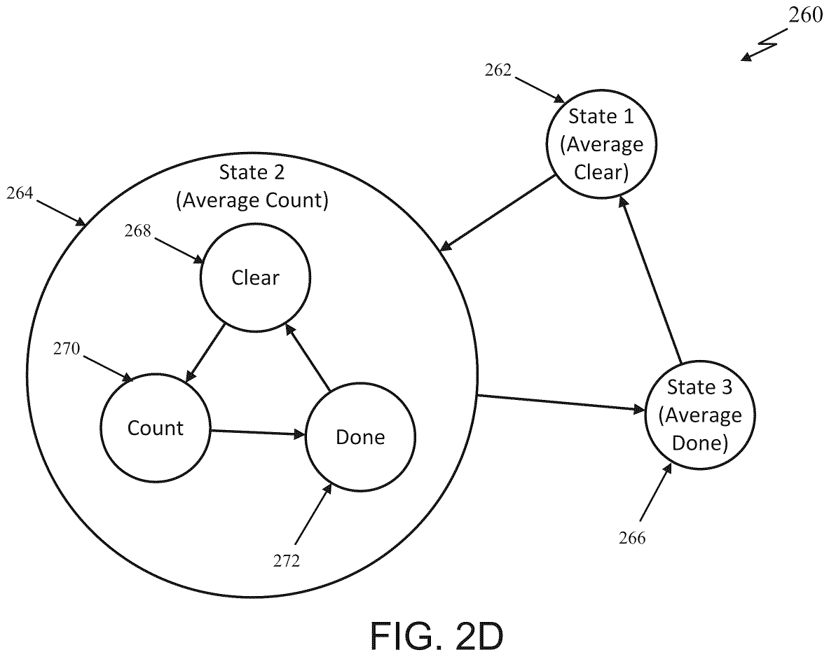

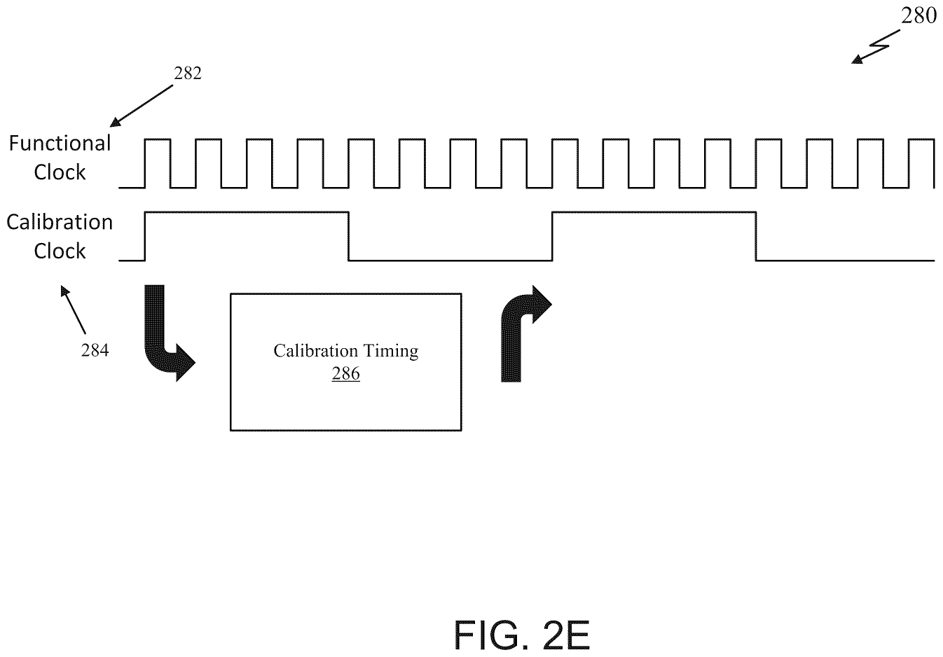

In operation, the external reference current source 102 may provide a reference current (I_{Ref}) to the VNMs 106 (e.g., each of the VNMs 106 may share a reference current that is provided from the external reference current source 102). In addition, a power source 104 may provide a supply voltage (V_{dd}) to the VNMs 106. The micro-processor 112 may be used to provide information such as threshold information (e.g., sixty-four configurable bits), mode information, and/or enable information to the VNMs 106. The noise mitigation circuitry 114 may be circuitry that is configured to receive an output from the VNM 106, and use the output to perform noise mitigation. Each of the VNMs 106 may include analog circuitry 108, which is described in FIG. 1B, and digital circuitry 110, which is described in FIG. 2. In some instances, the VNMs 106 may operate in continuous time and may be programmed to have a bandwidth from direct current (DC) to gigahertz (GHz) range.

FIG. 1B shows a block diagram of the analog circuitry 108 of a VNM 106 from FIG. 1A, in accordance with an embodiment. The analog circuitry 108 includes three fast voltage comparators 120-124, sense voltage circuitry (Vₛₑₙₛₑ circuitry) 118 that includes programmable sense voltage generators for each comparator with tunable filter for noise bandwidth, and a reference voltage generation with low-pass-filter (LPF) circuitry 116 that includes an input resistor with an LPF to create a voltage reference. The three comparators 120-124 (e.g., high comparator 120, middle comparator 122, and low comparator 124) enable detection of voltage noise events in different magnitudes. While three comparators 120-124 are shown in FIG. 1B, in other embodiments, the analog circuitry 108 may include any number of comparators including one, five, or greater than five comparators.

The inputs to the analog circuitry 108 may include the reference current (I_{Ref}) from the external reference current source 102, the supply voltage from the power source 104, and/or information from the microprocessor 112 such as enable information (e.g., an enable bit), mode information (e.g., a mode bit), and/or threshold information (e.g., high, medium, and low threshold bits). For instance, the reference current may be provided to the reference voltage generation with LPF circuitry 116, which is shown in FIG. 1C.

For instance, FIG. 1C shows an exemplary reference voltage generation circuitry 116, in accordance with an embodiment. The reference voltage generation circuitry 116 may include a capacitor (Cᵢₙ) 125, a ground 126, an untunable resistor (Rᵢₙ) 127, and an LPF (e.g., a resistor R_{LPF} 128 and a capacitor C_{LPF} 129). Based on the reference current, the reference voltage generation circuitry 116 may generate a reference voltage (V_{ref}) that is provided to the comparators 120-124. For instance, the reference voltage (V_{ref}) may be generated by feeding an external band gap current source (e.g., I_{Ref}), which is shared with other VNMs 106 into a resistor (e.g., Rᵢₙ 127). Using the external bandgap current reference (I_{Ref}) allows for a much tighter process and temperature variation for threshold settings. In conventional approaches, the reference voltage may be tunable to control the detection thresholds. However, in the VNMs 106, due to sharing of (I_{Ref}) among multiple VNMs 106, the resistor (Rᵢₙ) 127 of the reference voltage generation circuitry 116 may be kept constant to minimize variation, and instead, the tunability may be achieved using the Vₛₑₙₛₑ circuitry 118.

Returning back to FIG. 1B, the comparators 120-124 may receive two inputs-one from the reference voltage generation circuitry 116 (e.g., the reference voltage (V_{ref})) that is described above and another from the Vₛₑₙₛₑ circuitry 118 (e.g., the sense voltage (Vₛₑₙₛₑ)). For instance, each comparator 120-124 may receive the same reference voltage, but may receive different sense voltages (Vₛₑₙₛₑ) from the Vₛₑₙₛₑ circuitry 118. In other words, the Vₛₑₙₛₑ circuitry 118 may include as many individual circuits as there are comparators. For instance, in FIG. 1B, the Vₛₑₙₛₑ circuitry 118 may include three different Vₛₑₙₛₑ circuits, and each Vₛₑₙₛₑ circuit may be configured to provide a different Vₛₑₙₛₑ to one of the comparators 120-124.

FIG. 1D shows an exemplary Vₛₑₙₛₑ circuit 130, in accordance with an embodiment. Each Vₛₑₙₛₑ circuit 130 may include one or more tunable capacitors and/more resistors. For instance, as shown in FIG. 1D, each Vₛₑₙₛₑ circuit 130 may include another LPF (e.g., a tunable capacitor 138 and a tunable resistor (R2) 140), which determines the cut-off frequency of the voltage noise that is being monitored. Furthermore, each Vₛₑₙₛₑ circuit 130 may further include one or more additional tunable resistors. For instance, the additional tunable resistors include a first resistor R1 132 and another resistor (controlled resistor) R_{controlled} 134. The supply voltage (V_{dd}) is provided to the Vₛₑₙₛₑ circuit 130 and the Vₛₑₙₛₑ is provided to one of the comparators 120-124. As such, based on the Vₛₑₙₛₑ circuit 130, Vₛₑₙₛₑ may be expressed as:

$$Vsense = VDD ( \frac{R 2}{R 1 + R 2 + Rcontrolled} )$$

As mentioned above, the Vₛₑₙₛₑ circuitry 118 of FIG. 1B may include three Vₛₑₙₛₑ circuits 130. FIG. 1E shows an exemplary Vₛₑₙₛₑ circuitry 118 with three Vₛₑₙₛₑ circuits 130, in accordance with an embodiment. For instance, as shown, FIG. 1E includes three Vₛₑₙₛₑ circuits 130, and each of them includes a ground 142, two tunable resistors 146 and 148, and a capacitor 144. The capacitor 144 may be the capacitor 138 from FIG. 1D and the first tunable resistor 146 may be the tunable resistor 140 from FIG. 1D. In addition, the second tunable resistor 148 may be the resistors 132 and 134 from FIG. 1D given that the resistors 132 and 134 are in series. The V sense circuitry 118 may obtain the supply voltage (V_{dd}) and provide three Vₛₑₙₛₑ to the comparators 120-124.

Thus, returning to FIG. 1B, each comparator 120-124 may receive two inputs—Vₛₑₙₛₑ from one of the Vsense circuits 130 and V_{ref} from the reference voltage generation circuitry 116. The comparators 120-124, such as operational amplifiers, may compare the two inputs and output a result based on the comparison. Furthermore, the supply voltage (V_{dd}) may also be provided to the comparators 120-124. The comparators 120-124 may be tripped based on the below expressions:

$$Vsense = VDD ( \frac{R 2}{R 1 + R 2 + Rcontrolled} ) = Vref \to VDD = Vref ( 1 + \frac{R 1}{R 2} + \frac{Rcontrolled}{R 2} )$$

Therefore, as shown, based on controlling one or more of the tunable resistors of the Vₛₑₙₛₑ circuitry 118 (e.g., R_{controlled} 134), the VNMs 106 may control when one or more of the comparators 120-124 trip (e.g., provides a signal indicating a noise detection event). The tunable resistors (e.g., R_{controlled} 134) of the Vₛₑₙₛₑ circuitry 118 may be controlled based on the threshold information. For example, a high threshold (e.g., a “Threshold_Hi” signal), a middle threshold (e.g., a “Threshold_Mi” signal), and a low threshold (e.g., a “Threshold_Lo” signal) may be provided to the Vₛₑₙₛₑ circuitry 118. Each of the thresholds may be and/or include a plurality of bits (e.g., sixty-four bits), and may be provided and/or programmed by the micro-processor 112. As mentioned above, the Vₛₑₙₛₑ circuitry 118 having three Vₛₑₙₛₑ circuits 130 and FIG. 1B showing three comparators 120-124 is merely exemplary. Thus, in examples where the VNM 106 includes fewer or additional comparators and/or Vₛₑₙₛₑ circuits 130, the micro-processor 112 may provide fewer or additional thresholds (e.g., two, five, and/or ten thresholds).

FIG. 1F shows an exemplary controlled resistor 134 from FIG. 1D with switches 158-166 that are controlled utilizing the threshold information (e.g., signals 168-176), in accordance with an embodiment. For instance, the controlled resistor 134 may include a plurality of step resistors (Rₛₜₑₚ) 150-156 and a plurality of switches 158-166 that are controlled by the bits of the threshold information 168-176. For clarity, the “ . . . ” within FIG. 1F is used such that not all sixty-four bits, switches, and/or resistors are shown. Thus, between the step resistors 152 and 154 may include additional step resistors that are not shown in FIG. 1F. Furthermore, each of the step resistors may be associated with one or more switches and one or more bits from the threshold information (e.g., the step resistor 150 is associated with switch 160 and the threshold bit 170 (“threshold_*<62>”)) that are also not shown. For instance, as shown, the threshold information includes sixty-four bits, and thus, the controlled resistor 134 may include sixty-four step resistors and sixty-four switches. Each bit from the threshold information may control a separate switch that has a corresponding step resistor (e.g., the step resistor 156 may have a switch 166 that is controlled by the bit 176 (“threshold_*<0>”).

When activated (e.g., when the threshold bit is high or “1” such as the threshold bit 168 or 176), the switch closes (e.g., the switch associated with threshold bit such as the switch 160 or 166 associated with the threshold bit 168 or 176), which causes a short circuit. For instance, based on the 20^{th} bit being high, the 20^{th} switch closes and thus, the overall resistance of the controlled resistor 134 would be equal to Rₛₜₑₚ multiplied by 20. Similarly, based on the 32^{th} bit being high, the 32^{th} switch closes and thus, the overall resistance of the controlled resistor 134 would be equal to Rₛₜₑₚ multiplied by 32. In other words, in some embodiments, the threshold information may be one-hot encoded such that only a single bit is high at a time. Based on the above, the minimum threshold, step size, and detection range may be expressed as:

$$Minimum Threshold Level = Vref ( 1 + \frac{R 1}{R 2} )$$

$$Step Size = Vref ( \frac{Rcontrolled\_step}{R 2} )$$

$$Detection Range = Vref ( \frac{Rcontrolled\_full}{R 2} )$$

where Rcontrolled_step is the resistance from a single step resistor and Rcontrolled_full is the resistance from all of the step resistors (e.g., all sixty-four step resistors). Therefore, as an example, with a V_{ref} of 500 (mV), embodiments of the present disclosure may achieve a detection step size of 6 mV (dynamic range of 380 mV) to 12 mV (dynamic range of 760 mV). In addition, the minimum DC level of detection may be programmed by the micro-processor 112 between 500 mV to 1030 mV, which may cover the whole range for overshoot and undershoot application requirements within one VNM 106 due to the configurability of the resistors 132, 140, and 134 within the Vₛₑₙₛₑ circuit 130.

Returning back to FIG. 1B, the output of the comparators 120-124 may be provided to a multiplexer (MUX), which may be switched between two modes. For instance, the VNM 106 may receive mode information (e.g., from the micro-processor 112) indicating whether to detect for an overshoot noise event or an undershoot noise event. An overshoot noise event may be an event where the supply voltage (V_{dd}) is greater than a certain amount (e.g., a baseline amount). For instance, the power source 104 may be configured to provide 1.0 V. Due to noise, the actual supply voltage (V_{dd}) may be greater than 1.0 V such as 1.1 V. Based on the actual supply voltage being greater than a threshold, then an overshoot noise event may occur. Similarly, an undershoot noise event may be an event where the supply voltage (V_{dd}) is less than a certain amount (e.g., the power source 104 may be configured to provide 0.7 V, but the actual supply voltage (V_{dd}) may be 0.65 V). Using the two modes, the VNMs 106 may detect for overshoot noise events and/or undershoot noise events. For example, the VNM 106 may receive mode information (e.g., a mode bit) indicating whether to detect for an undershoot noise event (e.g., a mode bit of “0”) or an overshoot noise event (e.g., a mode bit of “1”). The mode bit may be provided to the multiplexer to control the multiplexer. In addition, the inputs to the multiplexer may include the output from one of the comparators 120-124 and an inverted output (e.g., by attaching an inverter to an input of the multiplexer) from one of the comparators 120-124. In some examples, an SoC may include multiple VNMs 106, and one or more of the VNMs 106 may be configured to detect for undershoot noise events and one or more of the other VNMs 106 may be configured to detect for overshoot noise events.

In other words, as an example, based on configuring the R_{controlled} 134 for the three Vₛₑₙₛₑ circuits 130, each of the comparators 120-124 may be tripped at a different threshold such as 900 mV for the first comparator 124 (e.g., the low noise detected comparator), 950 mV for the second comparator 122 (e.g., the middle noise detected comparator), and 1 V for the third comparator 120 (e.g., the high noise detected comparator). Therefore, if there is an overshoot noise of 975 mV, then the first and second comparators 122-124 may provide an output signal indicating a noise detection event (e.g., a low and middle noise detection event). But, the third comparator 120 might not provide an output signal indicating a noise detection event (e.g., that there is not a high noise detection event).

In some examples, the VNM 106 may be provided (e.g., from the micro-processor 112) enable information (e.g., one or more enable bits). The enable bits may enable and/or disable one or more of the comparators 120-124 from generating an output signal indicating a noise detection event. For example, the enable bits may be provided to the Vₛₑₙₛₑ circuitry 118, and may be configured to enable and/or disable one or more of the Vₛₑₙₛₑ circuits 130. For instance, based on the enable bit, one or more Vₛₑₙₛₑ circuits 130 within the Vₛₑₙₛₑ circuitry 118 may be disabled (e.g., the Vₛₑₙₛₑ circuits for the high and medium thresholds may be disabled) such that the reference voltage is always greater than the sense voltage from the Vₛₑₙₛₑ circuitry 118, and thus the output signal from the comparators 120-124 may always fail to indicate a noise detection event. Additionally, and/or alternatively, based on the enable bit, one or more comparators 120-124 associated with the one or more Vₛₑₙₛₑ circuits may also be disabled. For instance, the one or more comparators 120-124 may be disabled to lower the power consumption.

Afterwards, returning to FIG. 1A, the analog circuitry 108 may be configured to provide one or more output signals (e.g., an output signal indicating a high signal/“1” based on detecting a noise detection event or a low signal/“0” based on not detecting a noise detection event) to digital circuitry 110 of the VNM 106. For example, each comparator 120-124 may be configured to provide an output signal to a digital circuitry 110 associated with the comparator 120-124 (e.g., the VNM 106 may include three digital circuitries 110, and each comparator 120-124 provides an output signal to its own digital circuitry 110).

In other words, in some embodiments, each comparator 120-124 may have a different input stage with N-Type Metal-Oxide Semiconductor (NMOS) inputs and common source output stages for gain. V_{ref} may be generated by the reference voltage generation circuitry 116 based on providing the reference voltage generation circuitry 116 with an external band gap current source (e.g., the external reference current source 102), which may be shared with other VNMs 106. Using the external reference current source 102 may allow a much tighter process and temperature variation for threshold settings. Conventional approaches may control the detection thresholds by having tunability on the reference voltage (V_{ref}). However, in one or more embodiments of the present disclosure, due to sharing of I_{ref} from the external reference current source 102 among multiple VNMs 106, the resistor Rᵢₙ 127 of the reference voltage generation circuitry 116 may be kept constant to minimize variation, and tunability may be achieved by the Vₛₑₙₛₑ circuitry 118. In some embodiments, the LPF (e.g., the capacitor 140 and the tunable resistor 138) inside the Vₛₑₙₛₑ circuitry 118 may determine the cut-off frequency of the voltage noise that is to be monitored. In some embodiments, the VNM 106 may operate in continuous time and may be configured to have a bandwidth from direct current (DC) to gigahertz (GHz) range. In some embodiments, the VNM 106 may have the capability to have input pins, which may be used to disable the individual comparators 120-124 if the comparators 120-124 are not planning to be used.

Returning back to FIG. 1A, the VNM 106 may further include digital circuitry 110, which is described in FIG. 2A. FIG. 2A shows a block diagram of the digital circuitry 110 of a VNM 106 from FIG. 1A, in accordance with an embodiment. The digital circuitry 110 may include a set-reset (SR) latch 202, a synchronizer circuitry 204, a hold finite state machine (FSM) 206, and a sticky hold counter 208. For example, the analog comparator output (e.g., the output signal indicating a noise detection event) may be provided from the analog circuitry 108 to the digital circuitry 110. Once provided, the analog comparator output is provided to both the SR latch 202 and the synchronizer circuitry 204. Based on the analog comparator output indicating a noise detection event (e.g., a high signal or “1”), the SR latch 202 may set the output of the digital circuitry 110 to the analog comparator output (e.g., the high signal or “1”), which indicates detection of a noise detection event by the VNM 106 (e.g., an undershoot or an overshoot was detected by the VNM 106). In addition, at times, Vₛₑₙₛₑ and V_{ref} may be very close to each other such that the analog comparator output may constantly switch (e.g., from high, to low, to high, to low, and so on). Thus, rather than constantly switching the output of the VNM 106, the digital circuitry 110 may include a hold FSM 206 and a sticky hold counter 208 to ensure that once a noise detection event occurs, the detection remains (e.g., held at “1”) for a set time duration (e.g., 15 clock cycles). This will be described in FIG. 2B.

FIG. 2B shows a portion 209 of the digital circuitry 110 from FIG. 2A, in accordance with an embodiment. For example, the synchronizer circuitry 204 may include two synchronizers 210 and 212, which may be flip flops that accept one input and the clock signal (e.g., the clock signal associated with the SoC), and provide one output. In addition, the counter 222 of the sticky hold counter 208 as well as the SR latch 202 may also receive the clock signal.

In operation, a first synchronizer 210 may be provided the clock signal and the output from the SR latch 202, and output a noise detection synchronous signal to the hold FSM 206. For example, returning to FIG. 2A, once the SR latch 202 is engaged (e.g., provides an output signal indicating the noise detection event), the output of the SR latch 202 is provided as output to the noise mitigation circuitry 114 and also back to the synchronizer circuitry 204. Specifically, the output of the SR latch 202 is provided to the first synchronizer 210. The first synchronizer 210 synchronizes the output signal (e.g., the output signal that was originally provided from the analog circuit 108) with the clock signal, and provides the noise detection synchronous signal to the hold FSM 206.

The hold FSM 206 includes two states—a clear state 214 and a hold state 216. Further, the hold FSM 206 includes two arcs 218 and 220 that are used to transition between the clear state 214 and the hold state 216. For instance, based on the noise detection synchronous signal indicating the detection of a noise detection event, the hold FSM 206 transitions from the clear state 214 to the hold state 216, and engages the arc 218. The arc 218 provides a signal (e.g., engage (EN) signal) to the sticky hold counter 208. The sticky hold counter 208 includes a counter 222 that counts up based on the clock signal. Furthermore, the sticky hold counter 208 utilizes a threshold element 224 that is set to a certain number of clock cycles (e.g., 15 cycles), which may be pre-defined and/or user-defined (e.g., the “Threshold_Hold_Count” signal that is provided to the threshold element 224 indicating a certain number of clock cycles such as 15 cycles may be pre-defined and/or user-defined). For instance, for each clock cycle, the counter 222 may increment the count by one and check the count with a threshold element 224. Once reached, the sticky hold counter 208 provides a signal (e.g., a sticky hold done signal) back to the hold FSM 206.

The hold FSM 206 may transition from the hold state 216 back to the clear state 214 based on receiving the sticky hold done signal from the sticky hold counter 208 and an indication that the noise detection event (e.g., overshoot or undershoot) is no longer occurring. For example, the synchronizer circuitry 204 may further include a second synchronizer 212, which is provided as input the output from the analog circuit 106 and the clock signal. The output of the second synchronizer 212 may be inverted (e.g., by using an inverter 213) and provided to the arc 220. The arc 220 is used to transition the hold FSM 206 from the hold state 216 back to the clear state 214 based on the sticky hold done signal from the sticky hold counter 208 and the inverted signal from the second synchronizer 212 and the inverter 213. For instance, the inverted signal from the second synchronizer 212 may indicate whether the noise detection event is still being detected by the analog circuit 108. If so, the hold FSM 206 may determine to remain in the hold state 216, the counter 222 of the sticky hold counter 208 may be reset (e.g., based on providing a synchronous reset signal (“sync_RST” signal) or an asynchronous reset signal (“Async_RST” signal)), and the counter 222 may continue to be incremented until reaching the clock cycle threshold that is set by the threshold element 224. Then, the sticky hold counter 208 may provide the sticky hold done signal to the arc 220, and the arc 220 may check whether the inverted signal from the second synchronizer 212 and the inverter 213 continues to indicate a noise detection event.

Based on the sticky hold done signal and the inverted signal from the second synchronizer 212 indicating that the analog circuit 106 is no longer detecting a noise detection event, the hold FSM 206 may transition from the hold state 216 back to the clear state 214. After transitioning to the clear state 214, the hold FSM 206 may provide a reset signal to the SR latch 202, and the SR latch 202 may be reset. In other words, the SR latch 202 may be reset and the VNM 106 may indicate that the noise detection event has ended.

In other words, the noise detected outputs of the VNM 106 may be kept high (or sticky) with a programmable amount of clock cycles that may be determined by the digital circuitry 110. The VNM 106 outputs may also be kept in a thermometer nature based on an application or functionality requires the VNM 106 to do so.

Returning back to FIG. 1A, the VNM 106 provides an output (e.g., detection of the noise detection event such as an undershoot or overshoot event) to the noise mitigation circuitry 114. The noise mitigation circuitry 114 may perform noise mitigation, which is described in U.S. patent application Ser. No. 18/186,389 and is incorporated herein by reference. Additionally, and/or alternatively, the VNM 106 may provide an output to enable SRAM write and SRAM read assist circuits when the voltage is out of range. Additionally, and/or alternatively, based on the output from the VNM 106 indicating voltage undershoot events, the operation clock may be slowed.

In some embodiments, the VNM 106 and/or the micro-processor 112 may perform a calibration for the VNM 106. For example, each circuitry element, including the transistors and/or resistors, of the VNM 106 may include variations. For example, a 1000 Ohm resistor may actually provide a resistance value of 1002 Ohms or more. In some instances, such a deviation might not be significant. In other instances, such as when detecting the presence of a noise event, such deviations may become significant. As such, the VNM 106 and/or the micro-processor 112 may perform a calibration of the circuitry elements within the VNM 106 to ensure that the noise detection thresholds for the comparators 120-124 are set appropriately. For instance, initially, based on testing, the first resistor R1 132 and the second resistor R2 140 may be set for the VNM 106. Then, the micro-processor 112 and/or the VNM 106 may perform the calibration process below to calibrate the controlled resistor 134.

For example, the micro-processor 112 may set the power source 104 to two different voltages such as a high voltage (e.g., 1200 mV) and a low voltage (e.g., 1000 mV) and determine a code for each of the comparators 120-124 based on the set voltage (e.g., based on using a linear search process, method, and/or algorithm). For example, for a first comparator such as comparator 124, the micro-processor 112 may set the power source 104 to a high voltage (e.g., 1200 mV). Then, the micro-processor 112 may obtain a code that may be based on the set-up for the controlled resistor 134, which is shown in FIG. 1F above. For example, the VNM 106 may begin with the first switch for the first resistor (e.g., the switch 166 for the resistor 156) and activate the first switch, which as mentioned above, would set the resistance for the controlled resistor 134 to be Rₛₜₑₚ. Based on the high voltage (e.g., 1200 mV) being provided as the supply voltage to the Vₛₑₙₛₑ circuit 130 and the controlled resistor 134 being set to Rₛₜₑₚ, the comparator associated with the Vsense circuit 130 (e.g., the comparator 124) may provide an output indicating a high signal (“1”) or a low signal (“0”). For instance, initially, based on the controlled resistor 134 being set to Rₛₜₑₚ, the VNM 106 may check the output from the comparator 124. Based on the output being a low signal (e.g., due to the reference voltage being greater than the sense voltage from the Vsense circuit 130), the VNM 106 may active the second switch (e.g., the second switch 164 associated with the resistor 154). By activating the second switch (e.g., switch 164), the controlled resistor 134 may be set to a resistance of two times Rₛₜₑₚ. The VNM 106 may check the output from the comparator 124. The VNM 106 may continue activating switches and incrementing the resistance of the controlled resistor 134 by Rₛₜₑₚ until the comparator 124 outputs a high signal (“1”). Based on the comparator 124 outputting a high signal, the VNM 106 may output a code, which indicates the switch that was set for the comparator to output a high signal. For example, based on activating the switch for the 20^{th} resistor, the comparator 124 may output a high signal, and the VNM 106 may provide a code indicating the 20^{th} resistor/switch to the micro-processor 112. In other words, based on providing the first voltage (e.g., 1200 mV), the VNM 106 may continue to open and close switches starting from the first switch 166 associated with the first resistor 156, which increments the resistance for the controlled resistor 134 by Rₛₜₑₚ for each iteration, until the comparator outputs a high signal. The VNM 106 may determine the switch that was activated that caused the high signal and provide a code indicating the switch and resistor of the controlled resistor 134.

After setting and obtaining a code for the first voltage (e.g., 1200 mV), the micro-processor 112 may set the power source 104 to a second voltage such as 1000 mV. The VNM 106 may perform the calibration process described above and provide a second code indicating the switch and resistor of the controlled resistor 134 for the second voltage to the micro-processor 112. The micro-processor 112 may then determine or calculate a function (e.g., a transfer function) using the two codes and the two voltages. For instance, FIG. 2C represents an exemplary function that may be calculated based on the two codes and two voltages.

FIG. 2C shows a graphical representation 250 for calibrating the VNM 106, in accordance with an embodiment. For instance, the graphical representation 250 shows the code on the y-axis (e.g., between 0 and 60) and the voltage in mV on the x-axis (e.g., from 950 mV to 1250 mV). As such, the graphical representation 250 shows the code versus voltage from the calibration, which generates a transfer function denoted as a line 252.

For example, based on the two voltages (1000 mV and 1200 mV) and the two obtained codes (e.g., 15 for the first voltage (1000 mV) and 54 for the second voltage (1200 mV)), the micro-processor 112 may calculate a transfer function, which may be a linear relationship between the two voltages as shown in FIG. 2C (e.g., the line 252). Using the linear relationship (e.g., the line 252), the micro-processor 112 may determine the thresholds for that comparator. For instance, based on an indication to set the comparator to 1050 mV (e.g., the comparator is tripped at 1050 mV), the micro-processor 112 may determine, using the linear relationship, a code of 25. The micro-processor 112 may generate threshold information indicating the code of 25. For instance, the threshold information may be a plurality of bits such as sixty-four bits, and may be one hot encoded as described above. Based on the code indicating 25, the threshold information may have the 25^{th} bit set to “1” and the rest of the bits set to low “0”. Thus, based on providing the threshold information, the 25^{th} switch for the 25^{th} resistor may be activated, and the controller resistor 134 (R_{controlled}) may have a resistance value of Rₛₜₑₚ multiplied by 25.

In some instances, each Vₛₑₙₛₑ circuit 130 and its associated comparator of the VNM 106 may be calibrated separately as the circuitry elements within the individual Vₛₑₙₛₑ circuits 130 and/or comparator may deviate slightly from each other. For instance, as shown in FIGS. 1B, 1D, and 1E, there are three Vₛₑₙₛₑ circuits 130 and three comparators 120-124. Thus, the VNM 106 may be calibrated three times, one for each of the three Vₛₑₙₛₑ circuits 130 and comparators 120-124. As such, the micro-processor 112 and the VNM 106 may perform the calibration process described above and determine different codes for each Vₛₑₙₛₑ circuit 130 and its associated comparator. Then, the micro-processor 112 may calculate and/or determine a transfer function for each Vsense circuit 130 (e.g., the linear relationship 252 shown in FIG. 2C), and use the calculated transfer functions to determine the threshold information. In other instances, each of the Vₛₑₙₛₑ circuits 130 and their associated comparators might not be calibrated separately, and may instead be calibrated in parallel. As such, in such instances, the VNM 106 might not be calibrated three times, and one calibration process may be used to calibrate one or more (e.g., all) of the Vₛₑₙₛₑ circuits 130 and their associated comparators.

In other words, each comparator 120-124 may have a linear response as shown in FIG. 2C that may be slightly different from the other comparators 120-124. Thus, each comparators transfer function may be calculated using:

$$\frac{( y - code\_ * \_ 1 )}{( code\_ * \_ 1 - code\_ * \_ 2 )} = \frac{( x - VDD\_ 1 )}{( VDD\_ 1 - VDD\_ 2 )}$$

where y is the code to be programmed for x, where x is the threshold voltage to be used for detection. For instance, x may indicate the target voltage/threshold volume (e.g., 1050 mV in the example above) and y may indicate the correspondence code (e.g., 25 in the example above). In some instances, both code_*_1 and code_*_2 may be fused per comparator, which may be 12 bits.

In some examples, the micro-processor 112 and/or the VNM 106 may perform an averaging for the calibrations. For instance, during a first iteration of the calibration process for a first comparator 124, due to noise or other influences, the 20^{th} switch may have triggered the comparator 124 to indicate a high signal. To mitigate the noise and/or other influences, the micro-processor 112 and/or the VNM 106 may perform multiple calibration processes for each comparator 124. For example, the micro-processor 112 and/or the VNM 106 may perform the calibration process ten times for each comparator 124 and determine an average code based on the obtained codes. For instance, in the first iteration, the micro-processor 112 and/or the VNM 106 may determine the 20^{th} switch, in the second iteration, the micro-processor 112 and/or the VNM 106 may determine the 21^{st} switch, and so on. The micro-processor 112 and/or the VNM 106 may calculate an average and use the average to determine/calculate the transfer function and/or linear response/relationship. To perform the averaging for the calibrations, a calibration state machine may be used. For instance, based on the micro-processor 112 providing a calibration signal, the VNM 106 may execute a calibration state machine and return an average code. The calibration state machine is shown below in FIG. 2D.

FIG. 2D shows a calibration state machine 260 that is used to calibrate the VNM 106, in accordance with an embodiment. For instance, the calibration state machine 260 may include three states 262-266. Furthermore, one of the states, the average count state 264, may additionally include three states—a clear state 268, a count state 270, and a done state 272. For example, to enable efficient per-part calibration, the VNM 106 may implement a calibration FSM (e.g., the state machine 260) that outputs the code to be programmed for the given voltage. In particular, as mentioned above, based on the micro-processor 112 setting the power source 104 to a given voltage, the micro-processor 112 may provide a signal to the VNM 106 to begin the state machine 260. The state machine 260 may return a code for each Vₛₑₙₛₑ circuit 130 and the Vₛₑₙₛₑ circuit's 130 associated comparator 120-124, and this code may be an average of a plurality of codes (e.g., based on performing multiple calibration processes) to mitigate the noise and/or other influences. Then, the state machine 260 may generate another code for another voltage, and following, a transfer function (e.g., linear relationship) may be determined based on the two codes and the two voltages.

In other words, the state machine 260 may include two state machines—an averaging state machine that includes states 262-266 and a linear search state machine that is nested within the average count state 264. The linear search state machine includes states 268-272. The VNM 106 may execute/run the state machine 260, to return an average code that is then used to generate the transfer function (e.g., the linear relationship 252 shown in FIG. 2C). For instance, the VNM 106 may run the calibration a number of times to average the impact of the noise events during calibration. The two state machines within the state machine 260 are in nested structure (e.g., for each averaging step for states 262-266, the linear search state machine with stages 268-272 is performed).

In operation, based on receiving a calibration enable from the micro-processor 112, the state machine 260 begins and moves from the first state 262 to the second state 264 (e.g., the linear search state), and then to the third state 266. By performing the states 262-266, the state machine 260 may return an average code. For instance, in each iteration of performing the states 268-272 within the second state 264, a code may be determined (e.g., based on performing a linear search that sets switches for the tunable resistor R_{controlled} 134 to determine when the associated comparator indicates a noise event, which is described above). Then, after performing a number of iterations (e.g., ten iterations that are described as an example above), an average of the codes may be determined and returned by the state machine 260. The average code may be used to determine the transfer function for the Vₛₑₙₛₑ circuit 130 and its comparator.

In some instances, based on performing the state machine 260, a code may be determined for all of the Vₛₑₙₛₑ circuits 130 and their comparators 120-124 (e.g., a first, second, and third code may be determined for each of the Vₛₑₙₛₑ circuits 130 and its associated comparator 120-124). In some examples, during an iteration of states 268-272, the threshold information may saturate (e.g., the threshold information may progress to its last bit that sets its last switch from the tunable resistor R_{controlled} 134), but one or more of the comparators 120-124 might not trip (e.g., might not indicate detection of a noise event). In such instances, a calibration error signal may be generated by the state machine 260, and provided back to the micro-processor 112. This may cease the operation of the state machine 260 such that a final average code is not generated by the state machine 260. In some instances, the calibration of the VNM 106 may be performed in a divided version of the input clock (e.g., divided by eight or sixteen). For instance, the timing diagram that is used for the calibration of the VNM 106 is shown in FIG. 2E.

FIG. 2E shows a timing diagram 280 that is used to calibrate the VNM 106, in accordance with an embodiment. For example, the timing diagram 280 shows the functional clock 282 and the calibration clock 284. At the rising edge of the calibration clock 284 and before the next rising edge of the calibration block 284, a calibration timing 286 is shown. For instance, as described above, based on the calibration clock 284, the calibration timing 286 may include releasing the new threshold information (e.g., “new_threshold_*<5:0>_code”), the new threshold information may go through binary to one hot decoder, and the new Vₛₑₙₛₑ voltage may settle. The calibration timing 286 may further include the delay from the comparator (e.g., comparators 120-124) and the SR latch 202, and the delay from the synchronizer circuitry 204 (e.g., three cycles of the functional clock).

To put it another way, embodiments of the present disclosure may use a calibration method that offsets the inaccuracies due to the input I_{ref} current from the external reference current source 102 and hence the V_{ref} variations, Vₛₑₙₛₑ variations from the Vₛₑₙₛₑ circuitry 118 due to resistor mismatches, and comparator 120-124 random input offset variations across process and voltage.

The calibration method (e.g., a two-point voltage calibration method) that is described above may be summarized as:
1) Set the supply voltage to a first voltage (e.g., a high voltage) and obtain a code for the comparators 120-124 inside each VNM 106.
2) Set the supply voltage to a second voltage (e.g., a low voltage) and obtain a code for the comparators 120-124 inside each VNM 106.
3) Determine a linear response such as the line 252 from FIG. 2C based on using the two voltages and the two codes.

In some instances, to reduce the number of required fuses for the VNM 106, all VNMs that share the reference current from the external reference current source 102 may be grouped together. For instance all codes for all VNMs 106 and their comparators 120-124 may be collected, and therefore, the total number of fuses for the group may be 10+8*i*j where i is the number of VNMs 106 and j is the number of comparators within each VNM 106. For instance, for a group of 10 VNMs 106 that share the reference current and each employing three comparators 120-124, this may require 250 fuses whereas it would be 360 fuses without using one or more embodiments of the present disclosure.

After calibration, the error margin of a VNM 106 may be summarized based on the alternate current (AC) noise, calibration errors, and temperature variations (plus and minus). The AC noise may be −8 mV, the calibration error may be plus and minus 3 mV, and the temperature variation may be plus and minus 3 mV. The AC noise may be due to the noise associated with coupling to the reference current routing. This may indicate that the thresholds may be set within 20 mV accuracy after calibration.

In some instances, if there are not enough fuses for the individual comparators of the VNM 106, code averaging may be used and only 10 fuses may be employed. However, to be able to do this with an acceptable error margin, the comparator offset calibration may be performed since it becomes the most dominant source of error. The VNM 106 may have a FSM that performs static comparator offset calibration at one voltage and temperature point during chip boot. With only 10 fuses and comparator offset calibration, the error margins may include a −0.05 direct current (DC) offset of −7 mV, an AC noise of −8 mV, a first calibration error of −11 mV, a first temperature variation of −7 mV, a second temperature variation of +7 mV, a second calibration error of +11 mV, and a 0.5 DC offset of +7 mV. In such cases, the thresholds may be set within 58 mV of accuracy. Furthermore, the DC offset of 14 mV may be further reduced by using the sensor's location along the reference trace to improve the calibration error.

As such, in summary, the VNM 106 may have a clock source that is used only in the digital circuitry 110. Further, the VNM 106 might not be sensitive to clock jitter nor temperature, may use an analog reference, may have a latency of less than 1 nanosecond (ns), may have an area of 1350 μm², may have a power consumption of 1.5 milliWatts (mW), may have a resolution of 6 mV, and may have an accuracy of 20 mV with individual fuses.

Among other benefits and advantages, embodiments of the present disclosure provide a process that monitors for supply noise from a power source 104 using a VNM 106. In some instances, embodiments of the present disclosure include one or more VNMs 106 that includes sense voltage circuitry 118 comprising a controllable resistor 134 that is controlled using threshold information. The resistance of the controllable resistor 134 may be changed based on closing and/or opening one or more switches associated with step resistors using the bits from the threshold information. In some examples, the VNMs 106 may utilize a comparator to compare a sense voltage from sense voltage circuitry 118 with a reference voltage, and provide the output of the comparator to a multiplexer that operates in two modes. In the first mode, the VNM 106 may be configured to detect an overshoot event and in a second mode, the VNM 106 may be configured to detect an undershoot event. In some variations, the VNMs 106 may further include digital circuitry 110 that comprises a hold FSM 206 and a sticky hold counter 208. Using the digital circuitry 110, the VNMs 106 may be configured to hold the noise detection event for a plurality of clock cycles (e.g., based on a threshold within the sticky hold counter 208). In some instances, the VNMs 106 may also perform a calibration process by using two voltages for the power source 104 to obtain two codes. The VNMs 106 may determine a transfer function (e.g., linear relationship) based on the two voltages and the two codes, and use the transfer function to generate the threshold information for setting the resistance of the controllable resistors 134.

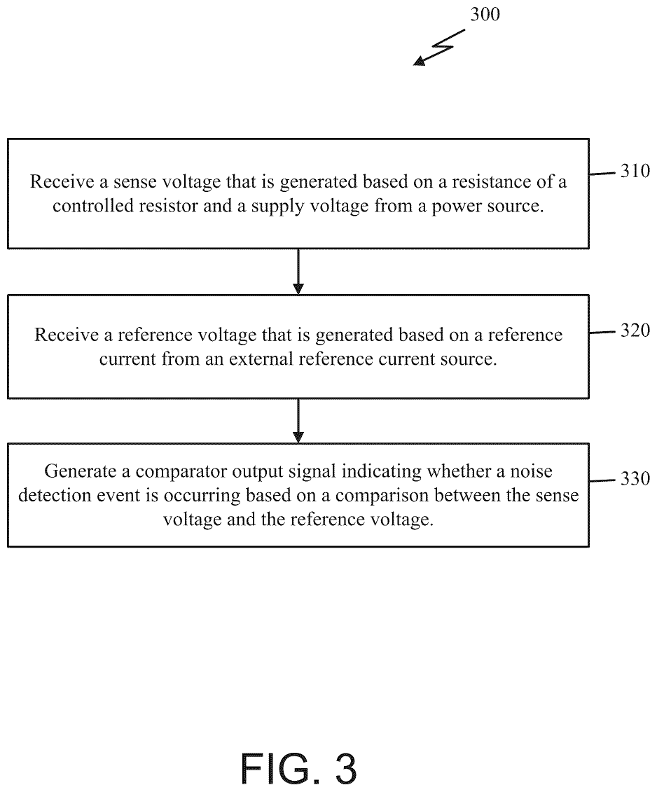

FIG. 3 provides a flow diagram illustrating a method 300 for using a VNM 106 to monitor for supply noise from a power source 104, in accordance with an embodiment. Each block of method 300, described herein, comprises a computing process that may be performed using any combination of hardware, firmware, and/or software. For instance, various functions may be carried out by a processor executing instructions stored in memory (e.g., the micro-processor 112 executing instruction stored in memory). The method 300 may be executed by any one system, or any combination of systems, including, but not limited to, those described herein. Furthermore, persons of ordinary skill in the art will understand that any system that includes a VNM 106 that performs method 300 is within the scope and spirit of embodiments of the present disclosure.

At step 310, a sense voltage (Vₛₑₙₛₑ) that is generated based on a resistance of a controller resistor 134 and a supply voltage from a power source 104 is received. For instance, the VNM 106 may include analog circuitry 108 that comprises Vₛₑₙₛₑ circuitry 118. The Vₛₑₙₛₑ circuitry 118 may include one or more Vₛₑₙₛₑ circuits 130, and each Vₛₑₙₛₑ circuit 130 includes a controlled resistor 134 that is tunable based on threshold information from a micro-processor 112. Each of the one or more Vₛₑₙₛₑ circuits 130 outputs the Vₛₑₙₛₑ based on a resistance of the controlled resistor 134 and a supply voltage from the power source 104. The comparator (e.g., one of the comparators 120-124) may receive the Vₛₑₙₛₑ.

At step 320, a reference voltage that is generated based on a reference current from an external reference current source 102 is received. For instance, the reference voltage generation circuitry 116 may generate the reference voltage, and the comparator may receive the reference voltage.

At step 330, a comparator output signal indicating whether a noise detection event is occurring based on a comparison between the Vₛₑₙₛₑ and the reference voltage is generated. For instance, the comparator may compare the Vₛₑₙₛₑ and the reference voltage, and generate an output signal indicating the noise detection event based on the comparison.

In an embodiment, the reference voltage generation circuitry 116 comprises a first LPF (e.g., the capacitor 129 and the resistor 128) and an untunable resistor 127, and the Vₛₑₙₛₑ circuitry 118 further comprises a first tunable resistor 132, and a second LPF comprising a second tunable resistor 140 and a capacitor 138. The generated Vₛₑₙₛₑ is based on a resistance of the first tunable resistor 132, a resistance of the second tunable resistor 140, the supply voltage, and the resistance of the controlled resistor 134.

In an embodiment, Vₛₑₙₛₑ is expressed as

$$Vsense = VDD ( \frac{R 2}{R 1 + R 2 + Rcontrolled} )$$

where V_{dd} is the supply voltage, R1 is the resistance of the first tunable resistor 132, R2 is the resistance of the second tunable resistor 140, and Rcontrolled is the resistance of the controlled resistor 134.

In an embodiment, each of the comparators 120-124 generates the comparator output signal based on the following:

$$VDD = Vref ( 1 + \frac{R 1}{R 2} + \frac{Rcontrolled}{R 2} )$$

where Vref is the reference voltage from the reference voltage generation circuitry 116.

In an embodiment, the analog circuitry further comprises a multiplexer. The multiplexer is configured to receive the comparator output signal and an inversion of the comparator output signal, receive mode information indicating selection of a first mode or a second mode. The first mode is associated with the VNM 106 operating to detect that the noise detection event is an overshoot event and the second mode is associated with the VNM 106 operating to detect that the noise detection event is an undershoot event. The multiplexer is further configured to output a multiplexer output signal based on the mode information, the comparator output signal, and the inversion of the comparator output signal.

In an embodiment, the controlled resistor 134 comprises a plurality of step resistors and a plurality of switches. Each of the plurality of switches is associated with a step resistor of the plurality of step resistors, and the resistance of the controlled resistor is set by closing a switch, from the plurality of switches, based on the threshold information.

In an embodiment, the threshold information comprises a plurality of bits and is one-hot-encoded, and the resistance of the controlled resistor 134 is set based on a bit, from the plurality of bits of the threshold information, that is set to “1”.

In an embodiment, the one or more Vsense circuits 130 comprises three Vₛₑₙₛₑ circuits 130 and the one or more comparators comprises three comparators 120-124 configured to output a first comparator output signal, a second comparator output signal, and a third comparator output signal. The first, second, and third comparator output signals are associated with different voltage thresholds that are based on different resistances of the controlled resistors 134 from the three Vsense circuits 130.

In an embodiment, the VNM 106 further comprises digital circuitry 110 configured to receive the comparator output signal from a comparator, of the one or more comparators 120-124, and output, for a plurality of clock cycles, a VNM output signal indicating detection of the noise detection event based on the comparator output signal indicating that the noise detection event is occurring.

In an embodiment, the digital circuitry 110 comprises a set-release (SR) latch 202 that is configured to receive the comparator output signal indicating that the noise detection event is occurring, set the VNM output signal to indicate the detection of the noise detection event, and reset the VNM output signal to indicate the noise detection event has ended based on receiving a reset signal from a hold finite state machine (FSM) 206.

In an embodiment, the digital circuitry 110 comprises the hold FSM 206 that is configured to transition from a clear state 214 to a hold state 216 based on the SR latch 202 setting the VNM output signal, transition from the hold state 216 back to the clear state 214 based on the plurality of clock cycles elapsing, and based on transition from the hold state 216 back to the clear state 214, provide the reset signal to the SR latch 202.

In an embodiment, the digital circuitry 110 further comprises a sticky hold counter 208 that is configured to enable a counter 222 based on receiving a signal indicating the hold FSM 206 transitioned from the clear state 214 to the hold state 216, increment the counter 222 after each clock cycle, and provide a sticky hold done signal to the hold FSM 206 based on comparing the count of the counter 222 with the set time duration. The transition from the hold state 216 back to the clear state 214 is based on the sticky hold done signal and an indication that the noise detection event has ended.

In an embodiment, the VNM 106 is further configured to calibrate the resistance of the controlled resistor 134 for a Vₛₑₙₛₑ circuit 130, of the one or more Vₛₑₙₛₑ circuits, based on a first set voltage from the power source 104, a second set voltage from the power source 104, a first code associated with the first set voltage, and a second code associated with the second set voltage.

In an embodiment, calibrating the resistance of the controlled resistor 134 comprises based on setting the power source 104 to the first set voltage, determining a first switch, from a plurality of switches of the controlled resistor 134, that trips a comparator, from the one or more comparators 120-124, determining the first code based on the first switch, based on setting the power source 104 to the second set voltage, determining a second switch, from a plurality of switches of the controlled resistor 134, that trips the comparator, and determining the second code based on the second switch. Further, each switch from the plurality of switches is associated with a code from the plurality of codes.

In an embodiment, calibrating the resistance of the controlled resistor 134 further comprises determining a transfer function based on the first set voltage, the second set voltage, the first code, and the second code. The transfer function indicates a linear relationship between the first set voltage/the first code and the second set voltage/the second code. The microprocessor 112 generates the threshold information based on the determined transfer function.

In an embodiment, calibrating the resistance of the controlled resistor is based on a calibration finite state machine (FSM) that averages a plurality of first codes associated with the first set voltage to determine the first code and averages a plurality of second codes associated with the second set voltage to determine the second code.

In an embodiment, at least one of steps 310-330 and/or the further steps described above for method 300 is performed within a server or in a data center. In an embodiment, at least one of steps 310-330 and/or the further steps described above for method 300 is performed within a cloud computing environment. In an embodiment, at least one of steps 310-330 and/or the further steps described above for method 300 is performed for training, testing, or certifying a neural network employed in a machine, robot, or autonomous vehicle. In an embodiment, at least one of steps 310-330 and/or the further steps described above for method 300 is performed on a virtual machine comprising a portion of a graphics processing unit.

In some examples, the VNM 106 may be used to detect undershoot noise and/or overshoot noise associated with a power supply 104. To detect the noise, the VNM 106 may include analog circuitry 108 and digital circuitry 110. For instance, the analog circuitry 108 may include sense voltage circuitry 118 comprising a controllable resistor 134 that is controlled using threshold information. In other words, the resistance of the controllable resistor 134 may be changed based on closing and/or opening one or more switches associated with step resistors using the bits from the threshold information. Furthermore, the VNM 106 may include a comparator and a multiplexer to operate in two modes—one for detecting an overshoot event and the other for detecting an undershoot event. In addition, the VNM 106 may include digital circuitry 110 that comprises a hold FSM 206 and a sticky hold counter 208. Using the digital circuitry 110, the VNMs 106 may be configured to hold the noise detection event for a plurality of clock cycles (e.g., based on a threshold within the sticky hold counter 208). Also, the VNM 106 may perform a calibration process using two voltages for the power source 104 to obtain two codes, and determine a transfer function (e.g., linear relationship) based on the two voltages and the two codes. The transfer function may be used generate the threshold information for setting the resistance of the controllable resistors 134.

### Parallel Processing Architecture

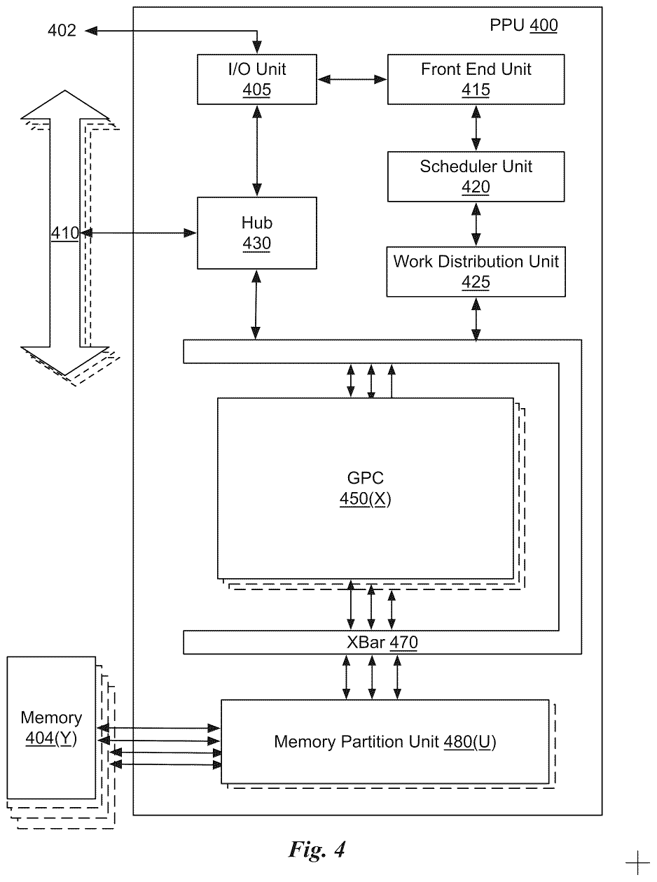

FIG. 4 illustrates a parallel processing unit (PPU) 400, in accordance with an embodiment. In an embodiment, the PPU 400 is a multi-threaded processor that is implemented on one or more integrated circuit devices. The PPU 400 is a latency hiding architecture designed to process many threads in parallel. A thread (e.g., a thread of execution) is an instantiation of a set of instructions configured to be executed by the PPU 400. In an embodiment, the PPU 400 is a graphics processing unit (GPU) configured to implement a graphics rendering pipeline for processing three-dimensional (3D) graphics data in order to generate two-dimensional (2D) image data for display on a display device. In other embodiments, the PPU 400 may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

One or more PPUs 400 may be configured to accelerate thousands of High Performance Computing (HPC), data center, cloud computing, and machine learning applications. The PPU 400 may be configured to accelerate numerous deep learning systems and applications for autonomous vehicles, simulation, computational graphics such as ray or path tracing, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

As shown in FIG. 4, the PPU 400 includes an Input/Output (I/O) unit 405, a front end unit 415, a scheduler unit 420, a work distribution unit 425, a hub 430, a crossbar (Xbar) 470, one or more general processing clusters (GPCs) 450, and one or more memory partition units 480. The PPU 400 may be connected to a host processor or other PPUs 400 via one or more high-speed NVLink 410 interconnect. The PPU 400 may be connected to a host processor or other peripheral devices via an interconnect 402. The PPU 400 may also be connected to a local memory 404 comprising a number of memory devices. In an embodiment, the local memory may comprise a number of dynamic random access memory (DRAM) devices. The DRAM devices may be configured as a high-bandwidth memory (HBM) subsystem, with multiple DRAM dies stacked within each device.

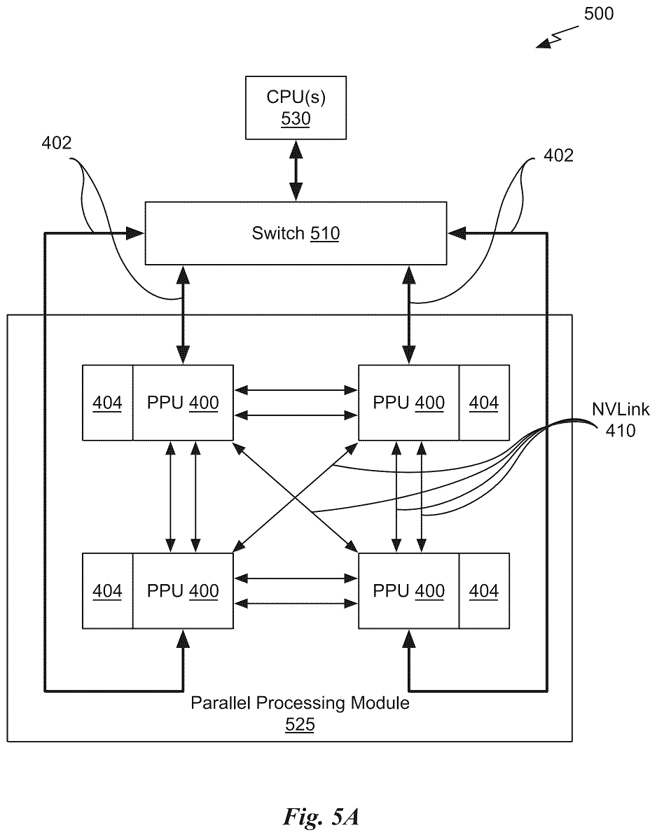

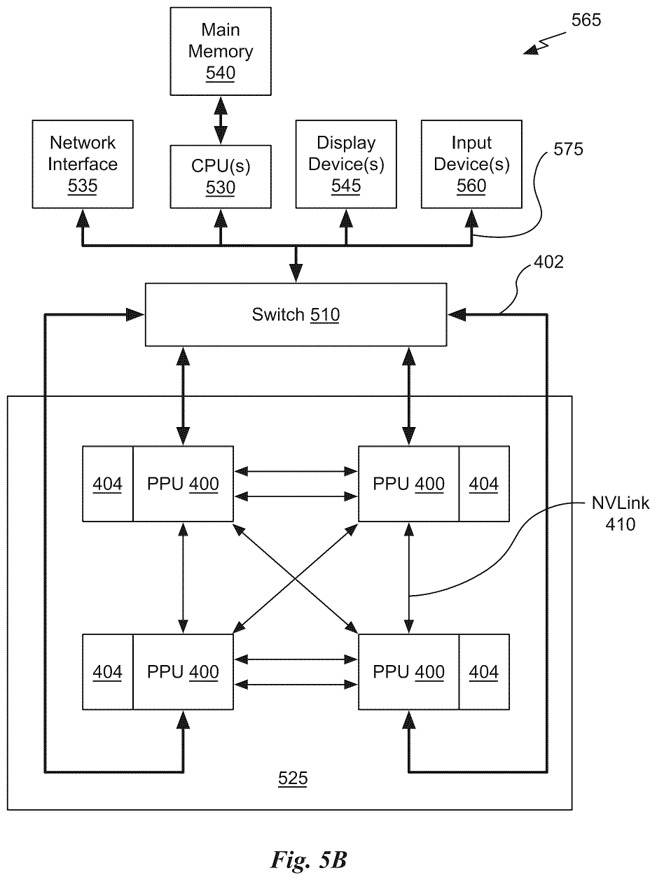

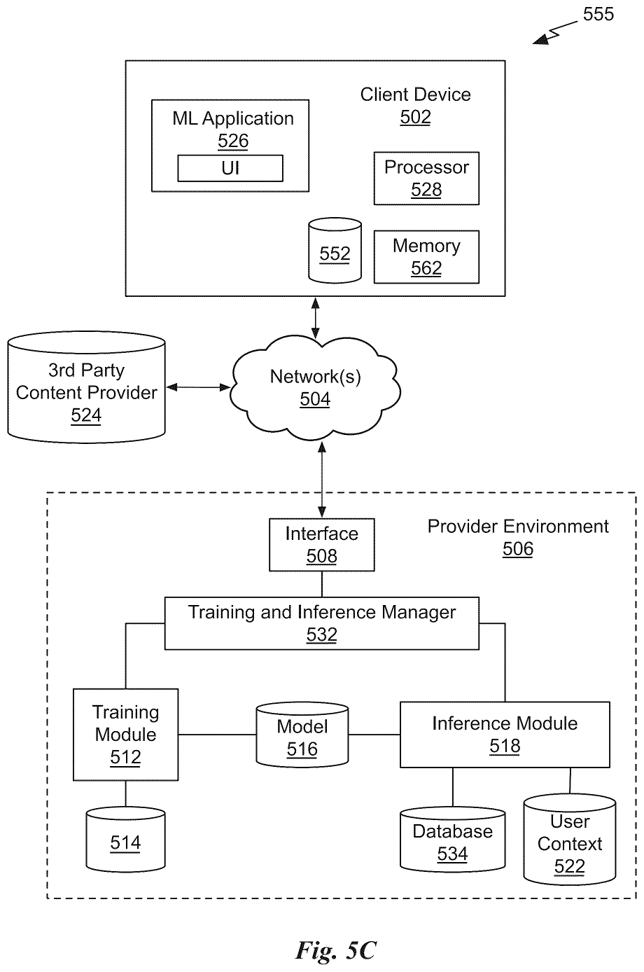

The NVLink 410 interconnect enables systems to scale and include one or more PPUs 400 combined with one or more CPUs, supports cache coherence between the PPUs 400 and CPUs, and CPU mastering. Data and/or commands may be transmitted by the NVLink 410 through the hub 430 to/from other units of the PPU 400 such as one or more copy engines, a video encoder, a video decoder, a power management unit, etc. (not explicitly shown). The NVLink 410 is described in more detail in conjunction with FIG. 5B.

The I/O unit 405 is configured to transmit and receive communications (e.g., commands, data, etc.) from a host processor (not shown) over the interconnect 402. The I/O unit 405 may communicate with the host processor directly via the interconnect 402 or through one or more intermediate devices such as a memory bridge. In an embodiment, the I/O unit 405 may communicate with one or more other processors, such as one or more the PPUs 400 via the interconnect 402. In an embodiment, the I/O unit 405 implements a Peripheral Component Interconnect Express (PCIe) interface for communications over a PCIe bus and the interconnect 402 is a PCIe bus. In alternative embodiments, the I/O unit 405 may implement other types of well-known interfaces for communicating with external devices.

The I/O unit 405 decodes packets received via the interconnect 402. In an embodiment, the packets represent commands configured to cause the PPU 400 to perform various operations. The I/O unit 405 transmits the decoded commands to various other units of the PPU 400 as the commands may specify. For example, some commands may be transmitted to the front end unit 415. Other commands may be transmitted to the hub 430 or other units of the PPU 400 such as one or more copy engines, a video encoder, a video decoder, a power management unit, etc. (not explicitly shown). In other words, the I/O unit 405 is configured to route communications between and among the various logical units of the PPU 400.

In an embodiment, a program executed by the host processor encodes a command stream in a buffer that provides workloads to the PPU 400 for processing. A workload may comprise several instructions and data to be processed by those instructions. The buffer is a region in a memory that is accessible (e.g., read/write) by both the host processor and the PPU 400. For example, the I/O unit 405 may be configured to access the buffer in a system memory connected to the interconnect 402 via memory requests transmitted over the interconnect 402. In an embodiment, the host processor writes the command stream to the buffer and then transmits a pointer to the start of the command stream to the PPU 400. The front end unit 415 receives pointers to one or more command streams. The front end unit 415 manages the one or more streams, reading commands from the streams and forwarding commands to the various units of the PPU 400.

The front end unit 415 is coupled to a scheduler unit 420 that configures the various GPCs 450 to process tasks defined by the one or more streams. The scheduler unit 420 is configured to track state information related to the various tasks managed by the scheduler unit 420. The state may indicate which GPC 450 a task is assigned to, whether the task is active or inactive, a priority level associated with the task, and so forth. The scheduler unit 420 manages the execution of a plurality of tasks on the one or more GPCs 450.

The scheduler unit 420 is coupled to a work distribution unit 425 that is configured to dispatch tasks for execution on the GPCs 450. The work distribution unit 425 may track a number of scheduled tasks received from the scheduler unit 420. In an embodiment, the work distribution unit 425 manages a pending task pool and an active task pool for each of the GPCs 450. As a GPC 450 finishes the execution of a task, that task is evicted from the active task pool for the GPC 450 and one of the other tasks from the pending task pool is selected and scheduled for execution on the GPC 450. If an active task has been idle on the GPC 450, such as while waiting for a data dependency to be resolved, then the active task may be evicted from the GPC 450 and returned to the pending task pool while another task in the pending task pool is selected and scheduled for execution on the GPC 450.

In an embodiment, a host processor executes a driver kernel that implements an application programming interface (API) that enables one or more applications executing on the host processor to schedule operations for execution on the PPU 400. In an embodiment, multiple compute applications are simultaneously executed by the PPU 400 and the PPU 400 provides isolation, quality of service (QoS), and independent address spaces for the multiple compute applications. An application may generate instructions (e.g., API calls) that cause the driver kernel to generate one or more tasks for execution by the PPU 400. The driver kernel outputs tasks to one or more streams being processed by the PPU 400. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory. The tasks may be allocated to one or more processing units within a GPC 450 and instructions are scheduled for execution by at least one warp.

The work distribution unit 425 communicates with the one or more GPCs 450 via XBar 470. The XBar 470 is an interconnect network that couples many of the units of the PPU 400 to other units of the PPU 400. For example, the XBar 470 may be configured to couple the work distribution unit 425 to a particular GPC 450. Although not shown explicitly, one or more other units of the PPU 400 may also be connected to the XBar 470 via the hub 430.

The tasks are managed by the scheduler unit 420 and dispatched to a GPC 450 by the work distribution unit 425. The GPC 450 is configured to process the task and generate results. The results may be consumed by other tasks within the GPC 450, routed to a different GPC 450 via the XBar 470, or stored in the memory 404. The results can be written to the memory 404 via the memory partition units 480, which implement a memory interface for reading and writing data to/from the memory 404. The results can be transmitted to another PPU 400 or CPU via the NVLink 410. In an embodiment, the PPU 400 includes a number U of memory partition units 480 that is equal to the number of separate and distinct memory devices of the memory 404 coupled to the PPU 400. Each GPC 450 may include a memory management unit to provide translation of virtual addresses into physical addresses, memory protection, and arbitration of memory requests. In an embodiment, the memory management unit provides one or more translation lookaside buffers (TLBs) for performing translation of virtual addresses into physical addresses in the memory 404.

In an embodiment, the memory partition unit 480 includes a Raster Operations (ROP) unit, a level two (L2) cache, and a memory interface that is coupled to the memory 404. The memory interface may implement 32, 64, 128, 1024-bit data buses, or the like, for high-speed data transfer. The PPU 400 may be connected to up to Y memory devices, such as high bandwidth memory stacks or graphics double-data-rate, version 5, synchronous dynamic random access memory, or other types of persistent storage. In an embodiment, the memory interface implements an HBM2 memory interface and Y equals half U. In an embodiment, the HBM2 memory stacks are located on the same physical package as the PPU 400, providing substantial power and area savings compared with conventional GDDR5 SDRAM systems. In an embodiment, each HBM2 stack includes four memory dies and Y equals 4, with each HBM2 stack including two 128-bit channels per die for a total of 8 channels and a data bus width of 1024 bits.

In an embodiment, the memory 404 supports Single-Error Correcting Double-Error Detecting (SECDED) Error Correction Code (ECC) to protect data. ECC provides higher reliability for compute applications that are sensitive to data corruption. Reliability is especially important in large-scale cluster computing environments where PPUs 400 process very large datasets and/or run applications for extended periods.

In an embodiment, the PPU 400 implements a multi-level memory hierarchy. In an embodiment, the memory partition unit 480 supports a unified memory to provide a single unified virtual address space for CPU and PPU 400 memory, enabling data sharing between virtual memory systems. In an embodiment the frequency of accesses by a PPU 400 to memory located on other processors is traced to ensure that memory pages are moved to the physical memory of the PPU 400 that is accessing the pages more frequently. In an embodiment, the NVLink 410 supports address translation services allowing the PPU 400 to directly access a CPU's page tables and providing full access to CPU memory by the PPU 400.

In an embodiment, copy engines transfer data between multiple PPUs 400 or between PPUs 400 and CPUs. The copy engines can generate page faults for addresses that are not mapped into the page tables. The memory partition unit 480 can then service the page faults, mapping the addresses into the page table, after which the copy engine can perform the transfer. In a conventional system, memory is pinned (e.g., non-pageable) for multiple copy engine operations between multiple processors, substantially reducing the available memory. With hardware page faulting, addresses can be passed to the copy engines without worrying if the memory pages are resident, and the copy process is transparent.

Data from the memory 404 or other system memory may be fetched by the memory partition unit 480 and stored in the L2 cache 460, which is located on-chip and is shared between the various GPCs 450. As shown, each memory partition unit 480 includes a portion of the L2 cache associated with a corresponding memory 404. Lower level caches may then be implemented in various units within the GPCs 450. For example, each of the processing units within a GPC 450 may implement a level one (L1) cache. The L1 cache is private memory that is dedicated to a particular processing unit. The L2 cache 460 is coupled to the memory interface 470 and the XBar 470 and data from the L2 cache may be fetched and stored in each of the L1 caches for processing.

In an embodiment, the processing units within each GPC 450 implement a SIMD (Single-Instruction, Multiple-Data) architecture where each thread in a group of threads (e.g., a warp) is configured to process a different set of data based on the same set of instructions. All threads in the group of threads execute the same instructions. In another embodiment, the processing unit implements a SIMT (Single-Instruction, Multiple Thread) architecture where each thread in a group of threads is configured to process a different set of data based on the same set of instructions, but where individual threads in the group of threads are allowed to diverge during execution. In an embodiment, a program counter, call stack, and execution state is maintained for each warp, enabling concurrency between warps and serial execution within warps when threads within the warp diverge. In another embodiment, a program counter, call stack, and execution state is maintained for each individual thread, enabling equal concurrency between all threads, within and between warps. When execution state is maintained for each individual thread, threads executing the same instructions may be converged and executed in parallel for maximum efficiency.

Cooperative Groups is a programming model for organizing groups of communicating threads that allows developers to express the granularity at which threads are communicating, enabling the expression of richer, more efficient parallel decompositions. Cooperative launch APIs support synchronization amongst thread blocks for the execution of parallel algorithms. Conventional programming models provide a single, simple construct for synchronizing cooperating threads: a barrier across all threads of a thread block (e.g., the syncthreads( ) function). However, programmers would often like to define groups of threads at smaller than thread block granularities and synchronize within the defined groups to enable greater performance, design flexibility, and software reuse in the form of collective group-wide function interfaces.

Cooperative Groups enables programmers to define groups of threads explicitly at sub-block (e.g., as small as a single thread) and multi-block granularities, and to perform collective operations such as synchronization on the threads in a cooperative group. The programming model supports clean composition across software boundaries, so that libraries and utility functions can synchronize safely within their local context without having to make assumptions about convergence. Cooperative Groups primitives enable new patterns of cooperative parallelism, including producer-consumer parallelism, opportunistic parallelism, and global synchronization across an entire grid of thread blocks.

Each processing unit includes a large number (e.g., 128, etc.) of distinct processing cores (e.g., functional units) that may be fully-pipelined, single-precision, double-precision, and/or mixed precision and include a floating point arithmetic logic unit and an integer arithmetic logic unit. In an embodiment, the floating point arithmetic logic units implement the IEEE 754-2008 standard for floating point arithmetic. In an embodiment, the cores include 64 single-precision (32-bit) floating point cores, 64 integer cores, 32 double-precision (64-bit) floating point cores, and 8 tensor cores.

Tensor cores configured to perform matrix operations. In particular, the tensor cores are configured to perform deep learning matrix arithmetic, such as GEMM (matrix-matrix multiplication) for convolution operations during neural network training and inferencing. In an embodiment, each tensor core operates on a 4×4 matrix and performs a matrix multiply and accumulate operation D=A×B+C, where A, B, C, and D are 4×4 matrices.

In an embodiment, the matrix multiply inputs A and B may be integer, fixed-point, or floating point matrices, while the accumulation matrices C and D may be integer, fixed-point, or floating point matrices of equal or higher bit-widths. In an embodiment, tensor cores operate on one, four, or eight bit integer input data with 32-bit integer accumulation. The 8-bit integer matrix multiply requires 1024 operations and results in a full precision product that is then accumulated using 32-bit integer addition with the other intermediate products for a 8×8×16 matrix multiply. In an embodiment, tensor Cores operate on 16-bit floating point input data with 32-bit floating point accumulation. The 16-bit floating point multiply requires 64 operations and results in a full precision product that is then accumulated using 32-bit floating point addition with the other intermediate products for a 4×4×4 matrix multiply. In practice, Tensor Cores are used to perform much larger two-dimensional or higher dimensional matrix operations, built up from these smaller elements. An API, such as CUDA 9 C++ API, exposes specialized matrix load, matrix multiply and accumulate, and matrix store operations to efficiently use Tensor Cores from a CUDA-C++ program. At the CUDA level, the warp-level interface assumes 16×16 size matrices spanning all 32 threads of the warp.

Each processing unit may also comprise M special function units (SFUs) that perform special functions (e.g., attribute evaluation, reciprocal square root, and the like). In an embodiment, the SFUs may include a tree traversal unit configured to traverse a hierarchical tree data structure. In an embodiment, the SFUs may include texture unit configured to perform texture map filtering operations. In an embodiment, the texture units are configured to load texture maps (e.g., a 2D array of texels) from the memory 404 and sample the texture maps to produce sampled texture values for use in shader programs executed by the processing unit. In an embodiment, the texture maps are stored in shared memory that may comprise or include an L1 cache. The texture units implement texture operations such as filtering operations using mip-maps (e.g., texture maps of varying levels of detail). In an embodiment, each processing unit includes two texture units.

Each processing unit also comprises N load store units (LSUs) that implement load and store operations between the shared memory and the register file. Each processing unit includes an interconnect network that connects each of the cores to the register file and the LSU to the register file, shared memory. In an embodiment, the interconnect network is a crossbar that can be configured to connect any of the cores to any of the registers in the register file and connect the LSUs to the register file and memory locations in shared memory.

The shared memory is an array of on-chip memory that allows for data storage and communication between the processing units and between threads within a processing unit. In an embodiment, the shared memory comprises 128 KB of storage capacity and is in the path from each of the processing units to the memory partition unit 480. The shared memory can be used to cache reads and writes. One or more of the shared memory, L1 cache, L2 cache, and memory 404 are backing stores.

Combining data cache and shared memory functionality into a single memory block provides the best overall performance for both types of memory accesses. The capacity is usable as a cache by programs that do not use shared memory. For example, if shared memory is configured to use half of the capacity, texture and load/store operations can use the remaining capacity. Integration within the shared memory enables the shared memory to function as a high-throughput conduit for streaming data while simultaneously providing high-bandwidth and low-latency access to frequently reused data.

When configured for general purpose parallel computation, a simpler configuration can be used compared with graphics processing. Specifically, fixed function graphics processing units, are bypassed, creating a much simpler programming model. In the general purpose parallel computation configuration, the work distribution unit 425 assigns and distributes blocks of threads directly to the processing units within the GPCs 450. Threads execute the same program, using a unique thread ID in the calculation to ensure each thread generates unique results, using the processing unit(s) to execute the program and perform calculations, shared memory to communicate between threads, and the LSU to read and write global memory through the shared memory and the memory partition unit 480. When configured for general purpose parallel computation, the processing units can also write commands that the scheduler unit 420 can use to launch new work on the processing units.

The PPUs 400 may each include, and/or be configured to perform functions of, one or more processing cores and/or components thereof, such as Tensor Cores (TCs), Tensor Processing Units (TPUs), Pixel Visual Cores (PVCs), Ray Tracing (RT) Cores, Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like.

The PPU 400 may be included in a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, and the like. In an embodiment, the PPU 400 is embodied on a single semiconductor substrate. In another embodiment, the PPU 400 is included in a system-on-a-chip (SoC) along with one or more other devices such as additional PPUs 400, the memory 404, a reduced instruction set computer (RISC) CPU, a memory management unit (MMU), a digital-to-analog converter (DAC), and the like.

In an embodiment, the PPU 400 may be included on a graphics card that includes one or more memory devices. The graphics card may be configured to interface with a PCIe slot on a motherboard of a desktop computer. In yet another embodiment, the PPU 400 may be an integrated graphics processing unit (iGPU) or parallel processor included in the chipset of the motherboard. In yet another embodiment, the PPU 400 may be realized in reconfigurable hardware. In yet another embodiment, parts of the PPU 400 may be realized in reconfigurable hardware.

### Exemplary Computing System

Systems with multiple GPUs and CPUs are used in a variety of industries as developers expose and leverage more parallelism in applications such as artificial intelligence computing. High-performance GPU-accelerated systems with tens to many thousands of compute nodes are deployed in data centers, research facilities, and supercomputers to solve ever larger problems. As the number of processing devices within the high-performance systems increases, the communication and data transfer mechanisms need to scale to support the increased bandwidth.

FIG. 5A is a conceptual diagram of a processing system 500 implemented using the PPU 400 of FIG. 4, in accordance with an embodiment. The processing system 500 includes a CPU 530, switch 510, and multiple PPUs 400, and respective memories 404.

The NVLink 410 provides high-speed communication links between each of the PPUs 400. Although a particular number of NVLink 410 and interconnect 402 connections are illustrated in FIG. 5B, the number of connections to each PPU 400 and the CPU 530 may vary. The switch 510 interfaces between the interconnect 402 and the CPU 530. The PPUs 400, memories 404, and NVLinks 410 may be situated on a single semiconductor platform to form a parallel processing module 525. In an embodiment, the switch 510 supports two or more protocols to interface between various different connections and/or links.

In another embodiment (not shown), the NVLink 410 provides one or more high-speed communication links between each of the PPUs 400 and the CPU 530 and the switch 510 interfaces between the interconnect 402 and each of the PPUs 400. The PPUs 400, memories 404, and interconnect 402 may be situated on a single semiconductor platform to form a parallel processing module 525. In yet another embodiment (not shown), the interconnect 402 provides one or more communication links between each of the PPUs 400 and the CPU 530 and the switch 510 interfaces between each of the PPUs 400 using the NVLink 410 to provide one or more high-speed communication links between the PPUs 400. In another embodiment (not shown), the NVLink 410 provides one or more high-speed communication links between the PPUs 400 and the CPU 530 through the switch 510. In yet another embodiment (not shown), the interconnect 402 provides one or more communication links between each of the PPUs 400 directly. One or more of the NVLink 410 high-speed communication links may be implemented as a physical NVLink interconnect or either an on-chip or on-die interconnect using the same protocol as the NVLink 410.

In the context of the present description, a single semiconductor platform may refer to a sole unitary semiconductor-based integrated circuit fabricated on a die or chip. It should be noted that the term single semiconductor platform may also refer to multi-chip modules with increased connectivity which simulate on-chip operation and make substantial improvements over utilizing a conventional bus implementation. Of course, the various circuits or devices may also be situated separately or in various combinations of semiconductor platforms per the desires of the user. Alternately, the parallel processing module 525 may be implemented as a circuit board substrate and each of the PPUs 400 and/or memories 404 may be packaged devices. In an embodiment, the CPU 530, switch 510, and the parallel processing module 525 are situated on a single semiconductor platform.

In an embodiment, the signaling rate of each NVLink 410 is 20 to 25 Gigabits/second and each PPU 400 includes six NVLink 410 interfaces (as shown in FIG. 5A, five NVLink 410 interfaces are included for each PPU 400). Each NVLink 410 provides a data transfer rate of 25 Gigabytes/second in each direction, with six links providing 400 Gigabytes/second. The NVLinks 410 can be used exclusively for PPU-to-PPU communication as shown in FIG. 5A, or some combination of PPU-to-PPU and PPU-to-CPU, when the CPU 530 also includes one or more NVLink 410 interfaces.

In an embodiment, the NVLink 410 allows direct load/store/atomic access from the CPU 530 to each PPU's 400 memory 404. In an embodiment, the NVLink 410 supports coherency operations, allowing data read from the memories 404 to be stored in the cache hierarchy of the CPU 530, reducing cache access latency for the CPU 530. In an embodiment, the NVLink 410 includes support for Address Translation Services (ATS), allowing the PPU 400 to directly access page tables within the CPU 530. One or more of the NVLinks 410 may also be configured to operate in a low-power mode.

FIG. 5B illustrates an exemplary system 565 in which the various architecture and/or functionality of the various previous embodiments may be implemented.

As shown, a system 565 is provided including at least one central processing unit 530 that is connected to a communication bus 575. The communication bus 575 may directly or indirectly couple one or more of the following devices: main memory 540, network interface 535, CPU(s) 530, display device(s) 545, input device(s) 560, switch 510, and parallel processing system 525. The communication bus 575 may be implemented using any suitable protocol and may represent one or more links or busses, such as an address bus, a data bus, a control bus, or a combination thereof. The communication bus 575 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, HyperTransport, and/or another type of bus or link. In some embodiments, there are direct connections between components. As an example, the CPU(s) 530 may be directly connected to the main memory 540. Further, the CPU(s) 530 may be directly connected to the parallel processing system 525. Where there is direct, or point-to-point connection between components, the communication bus 575 may include a PCIe link to carry out the connection. In these examples, a PCI bus need not be included in the system 565.

Although the various blocks of FIG. 5C are shown as connected via the communication bus 575 with lines, this is not intended to be limiting and is for clarity only. For example, in some embodiments, a presentation component, such as display device(s) 545, may be considered an I/O component, such as input device(s) 560 (e.g., if the display is a touch screen). As another example, the CPU(s) 530 and/or parallel processing system 525 may include memory (e.g., the main memory 540 may be representative of a storage device in addition to the parallel processing system 525, the CPUs 530, and/or other components). In other words, the computing device of FIG. 5C is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 5C.

The system 565 also includes a main memory 540. Control logic (software) and data are stored in the main memory 540 which may take the form of a variety of computer-readable media. The computer-readable media may be any available media that may be accessed by the system 565. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the main memory 540 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by system 565. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

Computer programs, when executed, enable the system 565 to perform various functions. The CPU(s) 530 may be configured to execute at least some of the computer-readable instructions to control one or more components of the system 565 to perform one or more of the methods and/or processes described herein. The CPU(s) 530 may each include one or more cores (e.g., one, two, four, eight, twenty-eight, seventy-two, etc.) that are capable of handling a multitude of software threads simultaneously. The CPU(s) 530 may include any type of processor, and may include different types of processors depending on the type of system 565 implemented (e.g., processors with fewer cores for mobile devices and processors with more cores for servers). For example, depending on the type of system 565, the processor may be an Advanced RISC Machines (ARM) processor implemented using Reduced Instruction Set Computing (RISC) or an x86 processor implemented using Complex Instruction Set Computing (CISC). The system 565 may include one or more CPUs 530 in addition to one or more microprocessors or supplementary co-processors, such as math co-processors.

In addition to or alternatively from the CPU(s) 530, the parallel processing module 525 may be configured to execute at least some of the computer-readable instructions to control one or more components of the system 565 to perform one or more of the methods and/or processes described herein. The parallel processing module 525 may be used by the system 565 to render graphics (e.g., 3D graphics) or perform general purpose computations. For example, the parallel processing module 525 may be used for General-Purpose computing on GPUs (GPGPU). In embodiments, the CPU(s) 530 and/or the parallel processing module 525 may discretely or jointly perform any combination of the methods, processes and/or portions thereof.

The system 565 also includes input device(s) 560, the parallel processing system 525, and display device(s) 545. The display device(s) 545 may include a display (e.g., a monitor, a touch screen, a television screen, a heads-up-display (HUD), other display types, or a combination thereof), speakers, and/or other presentation components. The display device(s) 545 may receive data from other components (e.g., the parallel processing system 525, the CPU(s) 530, etc.), and output the data (e.g., as an image, video, sound, etc.).

The network interface 535 may enable the system 565 to be logically coupled to other devices including the input devices 560, the display device(s) 545, and/or other components, some of which may be built in to (e.g., integrated in) the system 565. Illustrative input devices 560 include a microphone, mouse, keyboard, joystick, game pad, game controller, satellite dish, scanner, printer, wireless device, etc. The input devices 560 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the system 565. The system 565 may be include depth cameras, such as stereoscopic camera systems, infrared camera systems, RGB camera systems, touchscreen technology, and combinations of these, for gesture detection and recognition. Additionally, the system 565 may include accelerometers or gyroscopes (e.g., as part of an inertia measurement unit (IMU)) that enable detection of motion. In some examples, the output of the accelerometers or gyroscopes may be used by the system 565 to render immersive augmented reality or virtual reality.

Further, the system 565 may be coupled to a network (e.g., a telecommunications network, local area network (LAN), wireless network, wide area network (WAN) such as the Internet, peer-to-peer network, cable network, or the like) through a network interface 535 for communication purposes. The system 565 may be included within a distributed network and/or cloud computing environment.

The network interface 535 may include one or more receivers, transmitters, and/or transceivers that enable the system 565 to communicate with other computing devices via an electronic communication network, included wired and/or wireless communications. The network interface 535 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet.

The system 565 may also include a secondary storage (not shown). The secondary storage 610 includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner. The system 565 may also include a hard-wired power supply, a battery power supply, or a combination thereof (not shown). The power supply may provide power to the system 565 to enable the components of the system 565 to operate.

Each of the foregoing modules and/or devices may even be situated on a single semiconductor platform to form the system 565. Alternately, the various modules may also be situated separately or in various combinations of semiconductor platforms per the desires of the user. While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

### Example Network Environments

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the processing system 500 of FIG. 5A and/or exemplary system 565 of FIG. 5B—e.g., each device may include similar components, features, and/or functionality of the processing system 500 and/or exemplary system 565.

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example processing system 500 of FIG. 5B and/or exemplary system 565 of FIG. 5C. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a remote control, an appliance, a consumer electronic device, a workstation, an edge device, any combination of these delineated devices, or any other suitable device.

### Machine Learning

Deep neural networks (DNNs) developed on processors, such as the PPU 400 have been used for diverse use cases, from self-driving cars to faster drug development, from automatic image captioning in online image databases to smart real-time language translation in video chat applications. Deep learning is a technique that models the neural learning process of the human brain, continually learning, continually getting smarter, and delivering more accurate results more quickly over time. A child is initially taught by an adult to correctly identify and classify various shapes, eventually being able to identify shapes without any coaching. Similarly, a deep learning or neural learning system needs to be trained in object recognition and classification for it get smarter and more efficient at identifying basic objects, occluded objects, etc., while also assigning context to objects.

At the simplest level, neurons in the human brain look at various inputs that are received, importance levels are assigned to each of these inputs, and output is passed on to other neurons to act upon. An artificial neuron or perceptron is the most basic model of a neural network. In one example, a perceptron may receive one or more inputs that represent various features of an object that the perceptron is being trained to recognize and classify, and each of these features is assigned a certain weight based on the importance of that feature in defining the shape of an object.

A deep neural network (DNN) model includes multiple layers of many connected nodes (e.g., perceptrons, Boltzmann machines, radial basis functions, convolutional layers, etc.) that can be trained with enormous amounts of input data to quickly solve complex problems with high accuracy. In one example, a first layer of the DNN model breaks down an input image of an automobile into various sections and looks for basic patterns such as lines and angles. The second layer assembles the lines to look for higher level patterns such as wheels, windshields, and mirrors. The next layer identifies the type of vehicle, and the final few layers generate a label for the input image, identifying the model of a specific automobile brand.

Once the DNN is trained, the DNN can be deployed and used to identify and classify objects or patterns in a process known as inference. Examples of inference (the process through which a DNN extracts useful information from a given input) include identifying handwritten numbers on checks deposited into ATM machines, identifying images of friends in photos, delivering movie recommendations to over fifty million users, identifying and classifying different types of automobiles, pedestrians, and road hazards in driverless cars, or translating human speech in real-time.

During training, data flows through the DNN in a forward propagation phase until a prediction is produced that indicates a label corresponding to the input. If the neural network does not correctly label the input, then errors between the correct label and the predicted label are analyzed, and the weights are adjusted for each feature during a backward propagation phase until the DNN correctly labels the input and other inputs in a training dataset. Training complex neural networks requires massive amounts of parallel computing performance, including floating-point multiplications and additions that are supported by the PPU 400. Inferencing is less compute-intensive than training, being a latency-sensitive process where a trained neural network is applied to new inputs it has not seen before to classify images, detect emotions, identify recommendations, recognize and translate speech, and generally infer new information.

Neural networks rely heavily on matrix math operations, and complex multi-layered networks require tremendous amounts of floating-point performance and bandwidth for both efficiency and speed. With thousands of processing cores, optimized for matrix math operations, and delivering tens to hundreds of TFLOPS of performance, the PPU 400 is a computing platform capable of delivering performance required for deep neural network-based artificial intelligence and machine learning applications.

Furthermore, images generated applying one or more of the techniques disclosed herein may be used to train, test, or certify DNNs used to recognize objects and environments in the real world. Such images may include scenes of roadways, factories, buildings, urban settings, rural settings, humans, animals, and any other physical object or real-world setting. Such images may be used to train, test, or certify DNNs that are employed in machines or robots to manipulate, handle, or modify physical objects in the real world. Furthermore, such images may be used to train, test, or certify DNNs that are employed in autonomous vehicles to navigate and move the vehicles through the real world. Additionally, images generated applying one or more of the techniques disclosed herein may be used to convey information to users of such machines, robots, and vehicles.

FIG. 5C illustrates components of an exemplary system 555 that can be used to train and utilize machine learning, in accordance with at least one embodiment. As will be discussed, various components can be provided by various combinations of computing devices and resources, or a single computing system, which may be under control of a single entity or multiple entities. Further, aspects may be triggered, initiated, or requested by different entities. In at least one embodiment training of a neural network might be instructed by a provider associated with provider environment 506, while in at least one embodiment training might be requested by a customer or other user having access to a provider environment through a client device 502 or other such resource. In at least one embodiment, training data (or data to be analyzed by a trained neural network) can be provided by a provider, a user, or a third party content provider 524. In at least one embodiment, client device 502 may be a vehicle or object that is to be navigated on behalf of a user, for example, which can submit requests and/or receive instructions that assist in navigation of a device.

In at least one embodiment, requests are able to be submitted across at least one network 504 to be received by a provider environment 506. In at least one embodiment, a client device may be any appropriate electronic and/or computing devices enabling a user to generate and send such requests, such as, but not limited to, desktop computers, notebook computers, computer servers, smartphones, tablet computers, gaming consoles (portable or otherwise), computer processors, computing logic, and set-top boxes. Network(s) 504 can include any appropriate network for transmitting a request or other such data, as may include Internet, an intranet, an Ethernet, a cellular network, a local area network (LAN), a wide area network (WAN), a personal area network (PAN), an ad hoc network of direct wireless connections among peers, and so on.

In at least one embodiment, requests can be received at an interface layer 508, which can forward data to a training and inference manager 532, in this example. The training and inference manager 532 can be a system or service including hardware and software for managing requests and service corresponding data or content, in at least one embodiment, the training and inference manager 532 can receive a request to train a neural network, and can provide data for a request to a training module 512. In at least one embodiment, training module 512 can select an appropriate model or neural network to be used, if not specified by the request, and can train a model using relevant training data. In at least one embodiment, training data can be a batch of data stored in a training data repository 514, received from client device 502, or obtained from a third party provider 524. In at least one embodiment, training module 512 can be responsible for training data. A neural network can be any appropriate network, such as a recurrent neural network (RNN) or convolutional neural network (CNN). Once a neural network is trained and successfully evaluated, a trained neural network can be stored in a model repository 516, for example, that may store different models or networks for users, applications, or services, etc. In at least one embodiment, there may be multiple models for a single application or entity, as may be utilized based on a number of different factors.

In at least one embodiment, at a subsequent point in time, a request may be received from client device 502 (or another such device) for content (e.g., path determinations) or data that is at least partially determined or impacted by a trained neural network. This request can include, for example, input data to be processed using a neural network to obtain one or more inferences or other output values, classifications, or predictions, or for at least one embodiment, input data can be received by interface layer 508 and directed to inference module 518, although a different system or service can be used as well. In at least one embodiment, inference module 518 can obtain an appropriate trained network, such as a trained deep neural network (DNN) as discussed herein, from model repository 516 if not already stored locally to inference module 518. Inference module 518 can provide data as input to a trained network, which can then generate one or more inferences as output. This may include, for example, a classification of an instance of input data. In at least one embodiment, inferences can then be transmitted to client device 502 for display or other communication to a user. In at least one embodiment, context data for a user may also be stored to a user context data repository 522, which may include data about a user which may be useful as input to a network in generating inferences, or determining data to return to a user after obtaining instances. In at least one embodiment, relevant data, which may include at least some of input or inference data, may also be stored to a local database 534 for processing future requests. In at least one embodiment, a user can use account information or other information to access resources or functionality of a provider environment. In at least one embodiment, if permitted and available, user data may also be collected and used to further train models, in order to provide more accurate inferences for future requests. In at least one embodiment, requests may be received through a user interface to a machine learning application 526 executing on client device 502, and results displayed through a same interface. A client device can include resources such as a processor 528 and memory 562 for generating a request and processing results or a response, as well as at least one data storage element 552 for storing data for machine learning application 526.

In at least one embodiment a processor 528 (or a processor of training module 512 or inference module 518) will be a central processing unit (CPU). As mentioned, however, resources in such environments can utilize GPUs to process data for at least certain types of requests. With thousands of cores, GPUs, such as PPU 300 are designed to handle substantial parallel workloads and, therefore, have become popular in deep learning for training neural networks and generating predictions. While use of GPUs for offline builds has enabled faster training of larger and more complex models, generating predictions offline implies that either request-time input features cannot be used or predictions must be generated for all permutations of features and stored in a lookup table to serve real-time requests. If a deep learning framework supports a CPU-mode and a model is small and simple enough to perform a feed-forward on a CPU with a reasonable latency, then a service on a CPU instance could host a model. In this case, training can be done offline on a GPU and inference done in real-time on a CPU. If a CPU approach is not viable, then a service can run on a GPU instance. Because GPUs have different performance and cost characteristics than CPUs, however, running a service that offloads a runtime algorithm to a GPU can require it to be designed differently from a CPU based service.

In at least one embodiment, video data can be provided from client device 502 for enhancement in provider environment 506. In at least one embodiment, video data can be processed for enhancement on client device 502. In at least one embodiment, video data may be streamed from a third party content provider 524 and enhanced by third party content provider 524, provider environment 506, or client device 502. In at least one embodiment, video data can be provided from client device 502 for use as training data in provider environment 506.

In at least one embodiment, supervised and/or unsupervised training can be performed by the client device 502 and/or the provider environment 506. In at least one embodiment, a set of training data 514 (e.g., classified or labeled data) is provided as input to function as training data. In an embodiment, the set of training data may be used in a generative adversarial training configuration to train a generator neural network.

In at least one embodiment, training data can include images of at least one human subject, avatar, or character for which a neural network is to be trained. In at least one embodiment, training data can include instances of at least one type of object for which a neural network is to be trained, as well as information that identifies that type of object. In at least one embodiment, training data might include a set of images that each includes a representation of a type of object, where each image also includes, or is associated with, a label, metadata, classification, or other piece of information identifying a type of object represented in a respective image. Various other types of data may be used as training data as well, as may include text data, audio data, video data, and so on. In at least one embodiment, training data 514 is provided as training input to a training module 512. In at least one embodiment, training module 512 can be a system or service that includes hardware and software, such as one or more computing devices executing a training application, for training a neural network (or other model or algorithm, etc.). In at least one embodiment, training module 512 receives an instruction or request indicating a type of model to be used for training, in at least one embodiment, a model can be any appropriate statistical model, network, or algorithm useful for such purposes, as may include an artificial neural network, deep learning algorithm, learning classifier, Bayesian network, and so on. In at least one embodiment, training module 512 can select an initial model, or other untrained model, from an appropriate repository 516 and utilize training data 514 to train a model, thereby generating a trained model (e.g., trained deep neural network) that can be used to classify similar types of data, or generate other such inferences. In at least one embodiment where training data is not used, an appropriate initial model can still be selected for training on input data per training module 512.

In at least one embodiment, a model can be trained in a number of different ways, as may depend in part upon a type of model selected. In at least one embodiment, a machine learning algorithm can be provided with a set of training data, where a model is a model artifact created by a training process. In at least one embodiment, each instance of training data contains a correct answer (e.g., classification), which can be referred to as a target or target attribute. In at least one embodiment, a learning algorithm finds patterns in training data that map input data attributes to a target, an answer to be predicted, and a machine learning model is output that captures these patterns. In at least one embodiment, a machine learning model can then be used to obtain predictions on new data for which a target is not specified.

In at least one embodiment, training and inference manager 532 can select from a set of machine learning models including binary classification, multiclass classification, generative, and regression models. In at least one embodiment, a type of model to be used can depend at least in part upon a type of target to be predicted.

### Example Game Streaming System

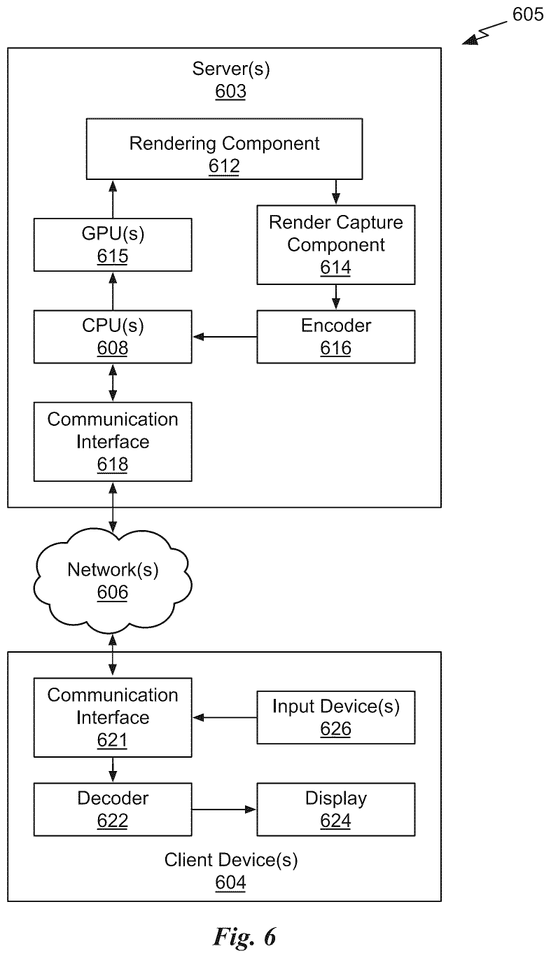

FIG. 6 is an example system diagram for a game streaming system 605, in accordance with some embodiments of the present disclosure. FIG. 6B includes game server(s) 603 (which may include similar components, features, and/or functionality to the example processing system 500 of FIG. 5A and/or exemplary system 565 of FIG. 5B), client device(s) 604 (which may include similar components, features, and/or functionality to the example processing system 500 of FIG. 5A and/or exemplary system 565 of FIG. 5B), and network(s) 606 (which may be similar to the network(s) described herein). In some embodiments of the present disclosure, the system 605 may be implemented.

In the system 605, for a game session, the client device(s) 604 may only receive input data in response to inputs to the input device(s), transmit the input data to the game server(s) 603, receive encoded display data from the game server(s) 603, and display the display data on the display 624. As such, the more computationally intense computing and processing is offloaded to the game server(s) 603 (e.g., rendering—in particular ray or path tracing—for graphical output of the game session is executed by the GPU(s) of the game server(s) 603). In other words, the game session is streamed to the client device(s) 604 from the game server(s) 603, thereby reducing the requirements of the client device(s) 604 for graphics processing and rendering.

For example, with respect to an instantiation of a game session, a client device 604 may be displaying a frame of the game session on the display 624 based on receiving the display data from the game server(s) 603. The client device 604 may receive an input to one of the input device(s) and generate input data in response. The client device 604 may transmit the input data to the game server(s) 603 via the communication interface 621 and over the network(s) 606 (e.g., the Internet), and the game server(s) 603 may receive the input data via the communication interface 618. The CPU(s) may receive the input data, process the input data, and transmit data to the GPU(s) that causes the GPU(s) to generate a rendering of the game session. For example, the input data may be representative of a movement of a character of the user in a game, firing a weapon, reloading, passing a ball, turning a vehicle, etc. The rendering component 612 may render the game session (e.g., representative of the result of the input data) and the render capture component 614 may capture the rendering of the game session as display data (e.g., as image data capturing the rendered frame of the game session). The rendering of the game session may include ray or path-traced lighting and/or shadow effects, computed using one or more parallel processing units-such as GPUs, which may further employ the use of one or more dedicated hardware accelerators or processing cores to perform ray or path-tracing techniques—of the game server(s) 603. The encoder 616 may then encode the display data to generate encoded display data and the encoded display data may be transmitted to the client device 604 over the network(s) 606 via the communication interface 618. The client device 604 may receive the encoded display data via the communication interface 621 and the decoder 622 may decode the encoded display data to generate the display data. The client device 604 may then display the display data via the display 624.

It is noted that the techniques described herein may be embodied in executable instructions stored in a computer readable medium for use by or in connection with a processor-based instruction execution machine, system, apparatus, or device. It will be appreciated by those skilled in the art that, for some embodiments, various types of computer-readable media can be included for storing data. As used herein, a “computer-readable medium” includes one or more of any suitable media for storing the executable instructions of a computer program such that the instruction execution machine, system, apparatus, or device may read (or fetch) the instructions from the computer-readable medium and execute the instructions for carrying out the described embodiments. Suitable storage formats include one or more of an electronic, magnetic, optical, and electromagnetic format. A non-exhaustive list of conventional exemplary computer-readable medium includes: a portable computer diskette; a random-access memory (RAM); a read-only memory (ROM); an erasable programmable read only memory (EPROM); a flash memory device; and optical storage devices, including a portable compact disc (CD), a portable digital video disc (DVD), and the like.

It should be understood that the arrangement of components illustrated in the attached Figures are for illustrative purposes and that other arrangements are possible. For example, one or more of the elements described herein may be realized, in whole or in part, as an electronic hardware component. Other elements may be implemented in software, hardware, or a combination of software and hardware. Moreover, some or all of these other elements may be combined, some may be omitted altogether, and additional components may be added while still achieving the functionality described herein. Thus, the subject matter described herein may be embodied in many different variations, and all such variations are contemplated to be within the scope of the claims.

To facilitate an understanding of the subject matter described herein, many aspects are described in terms of sequences of actions. It will be recognized by those skilled in the art that the various actions may be performed by specialized circuits or circuitry, by program instructions being executed by one or more processors, or by a combination of both. The description herein of any sequence of actions is not intended to imply that the specific order described for performing that sequence must be followed. All methods described herein may be performed in any suitable order unless otherwise indicated herein or otherwise clearly contradicted by context.

The use of the terms “a” and “an” and “the” and similar references in the context of describing the subject matter (particularly in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. Furthermore, the foregoing description is for the purpose of illustration only, and not for the purpose of limitation, as the scope of protection sought is defined by the claims as set forth hereinafter together with any equivalents thereof. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

What is claimed is:

1. A voltage noise monitor (VNM) configured to monitor supply noise from a power source, comprising:
analog circuitry comprising:
sense voltage (Vsense) circuitry comprising:
one or more Vsense circuits, wherein each of the one or more Vsense circuits comprises:
a controlled resistor that is tunable based on threshold information from a micro-processor, wherein each of the one or more Vsense circuits outputs Vsense based on a resistance of the controlled resistor and a supply voltage from the power source;
reference voltage generation circuitry configured to generate a reference voltage based on a reference current from an external reference current source; and
one or more comparators, wherein each of the one or more comparators is configured to:
receive the Vsense from a Vsense circuit of the one or more Vsense circuits;
receive the reference voltage from the reference voltage generation circuitry; and
generate a comparator output signal indicating whether a noise detection event is occurring based on a comparison between the Vsense and the reference voltage.

2. The VNM of claim 1, wherein the reference voltage generation circuitry comprises a first low pass filter (LPF) and an untunable resistor, and
wherein the Vsense circuitry further comprises:
a first tunable resistor; and
a second LPF comprising a second tunable resistor and a capacitor, wherein the generated Vsense is based on a resistance of the first tunable resistor, a resistance of the second tunable resistor, the supply voltage, and the resistance of the controlled resistor.

3. The VNM of claim 2, wherein the generated Vsense is based on the following:
$$Vsense = VDD ( \frac{R 2}{R 1 + R 2 + Rcontrolled} )$$
where Vdd is the supply voltage, R1 is the resistance of the first tunable resistor, R2 is the resistance of the second tunable resistor, and Rcontrolled is the resistance of the controlled resistor.

4. The VNM of claim 3, wherein each of the one or more comparators generates the comparator output signal based on the following:
$$VDD = Vref ( 1 + \frac{R 1}{R 2} + \frac{Rcontrolled}{R 2} )$$
where Vref is the reference voltage from the reference voltage generation circuitry.

5. The VNM of claim 1, wherein the analog circuitry further comprises:
a multiplexer configured to:
receive the comparator output signal and an inversion of the comparator output signal;
receive mode information indicating selection of a first mode or a second mode, wherein the first mode is associated with the VNM operating to detect that the noise detection event is an overshoot event and the second mode is associated with the VNM operating to detect that the noise detection event is an undershoot event; and
output a multiplexer output signal based on the mode information, the comparator output signal, and the inversion of the comparator output signal.

6. The VNM of claim 1, wherein the controlled resistor comprises:
a plurality of step resistors; and
a plurality of switches, wherein each of the plurality of switches is associated with a step resistor of the plurality of step resistors, and wherein the resistance of the controlled resistor is set by closing a switch, from the plurality of switches, based on the threshold information.

7. The VNM of claim 6, wherein the threshold information comprises a plurality of bits and is one-hot-encoded, and wherein the resistance of the controlled resistor is set based on a bit, from the plurality of bits of the threshold information, that is set to “1”.

8. The VNM of claim 1, wherein the one or more Vsense circuits comprises three Vsense circuits and the one or more comparators comprises three comparators configured to output a first comparator output signal, a second comparator output signal, and a third comparator output signal, and wherein the first, second, and third comparator output signals are associated with different voltage thresholds that are based on different resistances of the controlled resistors from the three Vsense circuits.

9. The VNM of claim 1, further comprising:
digital circuitry configured to:
receive the comparator output signal from a comparator, of the one or more comparators; and
output, for a plurality of clock cycles, a VNM output signal indicating detection of the noise detection event based on the comparator output signal indicating that the noise detection event is occurring.

10. The VNM of claim 9, wherein the digital circuitry comprises:
a set-release (SR) latch configured to:
receive the comparator output signal indicating that the noise detection event is occurring;
set the VNM output signal to indicate the detection of the noise detection event; and
reset the VNM output signal to indicate the noise detection event has ended based on receiving a reset signal from a hold finite state machine (FSM).

11. The VNM of claim 10, wherein the digital circuitry further comprises:
the hold FSM configured to:
transition from a clear state to a hold state based on the SR latch setting the VNM output signal;
transition from the hold state back to the clear state based on the plurality of clock cycles elapsing; and
based on transition from the hold state back to the clear state, provide the reset signal to the SR latch.

12. The VNM of claim 10, wherein the digital circuitry further comprises:
a sticky hold counter configured to:
enable a counter based on receiving a signal indicating the hold FSM transitioned from the clear state to the hold state;
increment the counter after each clock cycle; and
provide a sticky hold done signal to the hold FSM based on comparing the count of the counter with the set time duration, wherein the transition from the hold state back to the clear state is based on the sticky hold done signal and an indication that the noise detection event has ended.

13. The VNM of claim 1, wherein the VNM is further configured to:
calibrate the resistance of the controlled resistor for a Vsense circuit, of the one or more Vsense circuits, based on a first set voltage from the power source, a second set voltage from the power source, a first code associated with the first set voltage, and a second code associated with the second set voltage.

14. The VNM of claim 13, wherein calibrating the resistance of the controlled resistor comprises:
based on setting the power source to the first set voltage, determining a first switch, from a plurality of switches of the controlled resistor, that trips a comparator, from the one or more comparators;
determining the first code based on the first switch, wherein each switch from the plurality of switches is associated with a code from the plurality of codes;
based on setting the power source to the second set voltage, determining a second switch, from a plurality of switches of the controlled resistor, that trips the comparator; and
determining the second code based on the second switch.

15. The VNM of claim 14, wherein calibrating the resistance of the controlled resistor further comprises:
determining a transfer function based on the first set voltage, the second set voltage, the first code, and the second code, wherein the transfer function indicates a linear relationship between the first set voltage/the first code and the second set voltage/the second code, and wherein the microprocessor generates the threshold information based on the determined transfer function.

16. The VNM of claim 13, wherein calibrating the resistance of the controlled resistor is based on a calibration finite state machine (FSM) that averages a plurality of first codes associated with the first set voltage to determine the first code and averages a plurality of second codes associated with the second set voltage to determine the second code.

17. A method for monitoring supply noise from a power source using a voltage noise monitor (VNM), comprising:
receiving a sense voltage (Vsense) from a Vsense circuit of one or more Vsense circuits, wherein the VNM comprises analog circuitry that comprises Vsense circuitry and one or more comparators, wherein the Vsense circuitry comprises the one or more Vsense circuits, wherein each of the one or more Vsense circuits comprises a controlled resistor that is tunable based on threshold information from a micro-processor, and wherein each of the one or more Vsense circuits outputs a Vsense based on a resistance of the controlled resistor and a supply voltage from the power source;
receiving the reference voltage from a reference voltage generation circuitry, wherein the reference voltage is generated based on a reference current from an external reference current source; and
generating a comparator output signal indicating whether a noise detection event is occurring based on comparing, by a comparator from the one or more comparators, the Vsense and the reference voltage.

18. The method of claim 17, wherein the reference voltage generation circuitry comprises a first low pass filter (LPF) and an untunable resistor, and wherein the Vsense circuitry further comprises: a first tunable resistor and a second LPF comprising a second tunable resistor and a capacitor, wherein the generated Vsense is based on a resistance of the first tunable resistor, a resistance of the second tunable resistor, the supply voltage, and the resistance of the controlled resistor.

19. The method of claim 17, wherein at least one of the steps of receiving and generating are performed within a server or in a data center.

20. The method of claim 17, wherein at least one of the steps of receiving and generating are performed within a cloud computing environment.

21. The method of claim 17, wherein at least one of the steps of receiving and generating are performed for training, testing, or certifying a neural network employed in a machine, robot, or autonomous vehicle.

22. The method of claim 17, wherein at least one of the steps of receiving and generating are performed on a virtual machine comprising a portion of a graphics processing unit.

23. A system-on-chip (SoC), comprising:
a plurality of voltage noise monitors (VNMs) for monitoring supply noise from a power source, wherein each of the plurality of VNMs comprises:
analog circuitry comprising:
sense voltage (Vsense) circuitry comprising:
one or more Vsense circuits, wherein each of the one or more Vsense circuits comprises:
a controlled resistor that is tunable based on threshold information from a micro-processor, wherein each of the one or more Vsense circuits outputs Vsense based on a resistance of the controlled resistor and a supply voltage from the power source;
reference voltage generation circuitry configured to generate a reference voltage based on a reference current from an external reference current source; and
one or more comparators, wherein each of the one or more comparators is configured to:
receive the Vsense from a Vsense circuit of the one or more Vsense circuits;
receive the reference voltage from the reference voltage generation circuitry; and
generate a comparator output signal indicating whether a noise detection event is occurring based on a comparison between the Vsense and the reference voltage.

24. The system of claim 23, wherein the reference voltage generation circuitry comprises a first low pass filter (LPF) and an untunable resistor, and
wherein the Vsense circuitry further comprises:
a first tunable resistor; and
a second LPF comprising a second tunable resistor and a capacitor, wherein the generated Vsense is based on a resistance of the first tunable resistor, a resistance of the second tunable resistor, the supply voltage, and the resistance of the controlled resistor.
